(19) United States
(12) Patent Application Publication
(10) Pub. No.: US 2010/0108118 A1
(43) Pub. Date: May 6, 2010

(54) Photovoltaic power farm structure and installation

(76) Inventor: Daniel Luch, Morgan Hill, CA (US)

Correspondence Address: Daniel Luch, 17161 Copper Hill Drive, Morgan Hill, CA, 95037, US

(21) Appl. No.: 12/590,222

(22) Filed: Nov. 3, 2009

Related U.S. Application Data
(63) Continuation-in-part of application No. 12/156,505, filed on Jun. 2, 2008.

(51) Int. Cl. H01L 31/042

(52) U.S. Cl. 136/244

(57) ABSTRACT

Unique mounting structures and installation methods for arrays of photovoltaic modules are disclosed. These structures and methods allow for simple, inexpensive and facile production of expansive area solar energy collection facilities.

### CROSS REFERENCE TO RELATED APPLICATION

This application is a Continuation -in-Part of U.S. patent application Ser. No. 12/156,505, filed Jun. 2, 2008, pending, the entire contents of which are incorporated by this reference.

### BACKGROUND OF THE INVENTION

Photovoltaic cells have evolved according to two distinct materials and fabrication processes. A first is based on the use of single crystal or polycrystal silicon. The basic cell structure here is defined by the processes available for producing crystalline silicon wafers. The basic form of the wafers is typically a rectangle (such as 6 in.×6 in.) having a thickness of about 0.008 inch. Appropriate doping and heat treating produces individual cells having similar dimensions (6 in.×6 in.). These individual cells are normally subsequently assembled into an array of interconnected cells referred to as a module. A module may typically consist of multiple individual cells connected in series. The series connections may be made by individually connecting a conductor (tab) between the top electrode of one cell to the bottom electrode of an adjacent cell. In this way multiple cells are connected in a “string”. This legacy approach is generally referred to as the “string and tab” interconnection. Eventually, strings of cells are positioned and encapsulated in a box-like container. Typical dimensions for such containers may be 3.5 ft.×5 ft. Flexible electrical leads in the form of wires or ribbons extend from cells at opposite ends of the string. These leads of opposite polarity are often directed through a junction box before connections are made to a remote load or adjacent series connected module. Thus, the module can be considered its own self contained power plant.

The material and manufacturing costs of the crystalline silicon modules are relatively high. In addition, the practical size of the individual module is restricted by weight and batch manufacturing techniques employed. Nevertheless, the crystal silicon photovoltaic modules are quite suitable for small scale applications such as residential roof top applications and off-grid remote power installations. In these applications the crystal silicon cells have relatively high conversion efficiency and proven long term reliability and their restricted form factor has not been an overriding problem. A typical installation involves mounting the individual modules on a supporting structure and interconnecting using flexible leads or cabling from the individual junction boxes. Installation may often be characterized as “custom designed” for the specific site, which further increases cost. Because of cost, weight and size restrictions, use of crystalline photovoltaic cells for bulk power generation has developed only slowly in the past.

A second approach to photovoltaic cell manufacture comprises the so-called thin film structure. Here thin films (thickness of the order of microns) of appropriate semiconductors are deposited on a supporting substrate or superstrate. Thin films may be deposited over expansive areas. Indeed, many of the manufacturing techniques for thin film photovoltaic cells take advantage of this ability, employing relatively large glass substrates or continuous processing such as roll-to-roll manufacture using flexible continuous substrates. However, many thin films require heat treatments which are destructive of even the most temperature resistant polymers. Thus, thin films such as CIGS, CdTe and a-silicon are often deposited on glass or a metal foil such as stainless steel or aluminum. Deposition on glass surfaces restricts the ultimate module size and intrinsically involves output in batch form. In addition deposition on glass normally forces expensive and delicate material removal processing such as laser scribing to subdivide the expansive surface into individual interconnected cells remaining on the original glass substrate (often referred to as monolithic integration). Finally, it is difficult to incorporate collector electrodes over the top light incident surface of cells when employing glass superstrates. This often forces cell widths to be relatively small, typically about 0.5 cm. to 1.0 cm. Series interconnecting the large number of resulting individual cells may result in large voltages for a particular module which may be hazardous and require additional expense to insure against electrical shock.

Deposition of thin film semiconductors on a metal foil such as stainless steel or aluminum can be accomplished over expansive surfaces. However, because the substrate is conductive, monolithic integration techniques used for nonconductive substrates may be impractical. Thus, integration approaches for metal foil substrates generally envision subdivision into individual cells which can be subsequently interconnected. However handling, repositioning and integration of the multiple individual cells has proven troublesome. One technique is to use the “string and tab” approach developed for crystalline silicon cells referred to above. Such an approach reduces the ultimate value of continuous thin film production by introducing a tedious, expensive batch “back end” assembly process. In addition, such techniques do not produce modular forms conducive to large scale, expansive surface coverage requirements intrinsic for solar farms producing bulk power.

A further issue that has impeded adoption of photovoltaic technology for bulk power collection in the form of solar farms involves installation of multiple modules over expansive regions of surface. Traditionally, multiple individual modules have been mounted on racks, normally at an incline to horizontal appropriate to the latitude of the site. Flexible conducting leads or cabling from each module are then physically coupled with similar flexible leads from an adjacent module in order to interconnect multiple modules. This arrangement results in a string of modules each of which is coupled to an adjacent module. At one end of the string, the power is transferred from the end module and conveyed to a separate site for further power conditioning such as voltage adjustment. This arrangement avoids having to run conductive cabling from each individual module to the separate conditioning site.

The traditional solar farm installation described in the above paragraph has some drawbacks. First, the module itself comprises a string of individual cells. In the conventional module lead conductors in the form of flexible wires or ribbons are attached to an electrode on the two cells positioned at each end of the string in order to convey the power from the module. One problem is that the attachment of leads to the cell strings is normally a manual operation requiring tedious operations such as soldering. Next, the unwieldy flexible leads must be directed and secured in position outside the boundaries of the module, again a tedious operation. Finally, after mounting the module on its support at the installation site, the respective leads from adjacent modules must be connected in order to couple adjacent modules, and the connection must be protected to avoid environmental deterioration or separation. These are intrinsically tedious manual operations. Finally, since the module leads and cell interconnections are not of high current carrying capacity, the adjacent cells are normally connected in series arrangement. Thus voltage builds up to high levels even with a relatively small number of interconnected modules. Thus, skilled labor having electrical awareness is normally required for bulk installation. Finally, security and insulation must be appropriate to eliminate a shock hazard while in operation.

A unique technology for modularization of thin film cells deposited on expansive metal foil substrates is taught by Luch in U.S. Pat. Nos. 5,547,516, 5,735,966, 6,459,032, 6,239,352, 6,414,235, 7,507,903 and U.S. patent application Ser. Nos. 11/404,168, 11/824,047, 11/980,010, and 12/290,896. The entire contents of the aforementioned Luch patents and applications are hereby incorporated by reference. The Luch modules are manufactured by optionally subdividing metal foil/semiconductor structure into individual cells which may be subsequently recombined into series connected modules in continuous automated fashion. The final Luch array structures can be quite expansive (i.e. 2 ft. by 8 ft., 4 ft. by 8 ft., 8 ft. by 20 ft., 8 ft. by continuous length etc.). Thus Luch taught modules having low cost and optionally large form factors.

However, there remains a need for structure and methods allowing inexpensive installation of photovoltaic modules over large surface areas such as terrestrial surfaces and large commercial and possibly residential building rooftops.

### OBJECTS OF THE INVENTION

An object of the invention is to teach structure and methods allowing improved installation of photovoltaic modules over expansive surface areas.

A further object of the invention is to teach methods to reduce cost and complexity of photovoltaic power installations.

### SUMMARY OF THE INVENTION

The invention teaches structure and methodology to achieve installed photovoltaic modules covering expansive surfaces. The invention may employ large form factors of photovoltaic modules such as those taught in the aforementioned U.S. Patents and U.S. Patent Applications of Luch. However, other forms of expansive modular arrays may also be employed.

In an embodiment a mounting structure suitable for receiving photovoltaic modules is constructed at the installation site prior to installation of the individual photovoltaic modules.

In an embodiment a module is mounted on transportable pallet-like structures prior to field installation.

In an embodiment a mounting structure suitable for receiving a module of extended length is constructed at the installation site. An extended length module in roll form is shipped to the site and the module is applied to the structure by simply rolling out the module over the mounting structure. Power output connections are made at each end of the extended length module.

In an embodiment a mounting structure supports a module above a base surface with a space between the module and base surface.

In an embodiment a mounting structure serves as a major support for the modules and may also serve to position conductive rails for conveying the power from multiple modules.

In one embodiment the power conveying rails form a portion of the mounting structure for the modules.

In an embodiment conductive buss rails contribute to supporting the modules.

In one embodiment the power conveying rails contribute to a frame designed for conveniently receiving a module of predetermined geometry.

In an embodiment a flexible module is attached directly to a roof and rails are attached to collect current from the modules.

In an embodiment a mounting structure comprises a mesh structure to assist supporting a large area module.

In an embodiment a mounting structure comprises a ballast material intended to supply stabilizing weight to the structure.

In an embodiment a ballast material of the mounting structure comprises water.

In an embodiment a ballast material of the mounting structure comprises concrete.

In an embodiment the mounting structure comprises multiple water filled tanks.

In an embodiment multiple modules, each mounted on a transportable pallet-like structure, are arranged adjacent each other and connected by current carrying rails.

In an embodiment a module is mounted on a transportable pallet-like structure comprising a molded tank. The tank may be filled with liquid to supply both weight and thermal ballast.

In an embodiment an interconnecting structure comprises elongate rails which may comprise metal having high current carrying capacity such as aluminum or copper.

In an embodiment multiple individual modules form series connected portions of a large scale deployment and multiple series connected portions are interconnected in parallel.

In an embodiment the installed modules are supplied with environmental protection by applying sheets of transparent material after the modules have been installed onto the mounting structure.

In an embodiment the modules comprise a sheet of transparent material supplying environmental protection applied prior to installing the modules onto the mounting structure.

In an embodiment the module comprises a sealing gasket positioned outside a surface area defined by active photovoltaic semiconductor.

In an embodiment a desiccant is positioned within a perimeter defined by a sealing gasket.

In an embodiment module manufacture comprises roll lamination of a flexible arrangement of multiple interconnected cells to a glass sheet.

In an embodiment the modules may comprise thin film photovoltaic cells.

In an embodiment the photovoltaic cells comprise thin film semiconductor material supported on a metal foil.

In an embodiment the module is absent flexible, unwieldy conductive wire or ribbon leads extending from the module surface.

In an embodiment the module comprises terminal bars of opposite polarity.

In an embodiment the module comprises terminal bars of opposite polarity having a conductive surface at least partially positioned outside a boundary of an overlaying transparent protective layer.

In an embodiment the module comprises a terminal bar having monolithic structure common with a current collector structure of an end cell of the module.

In an embodiment the terminal bars extend over substantially the entire width of the module

In an embodiment individual cells extend substantially the entire width of a module and the terminal bars are positioned at opposite ends of the module length dimension.

In an embodiment the terminal bars provide an upward facing conductive surface.

In an embodiment a terminal bar has oppositely facing conductive surfaces in electrical communication.

In an embodiment the terminal bars have attachment structure such as through holes which is complimentary to attachment structure present on metal rails.

In an embodiment a fastener is used to connect a module to a rail.

In an embodiment a rigid electrical connection is made between a terminal bar and a conductive rail.

In an embodiment a fastener connecting a module to a rail is a mechanical fastener.

In an embodiment a fastener connecting a module to a rail is characterized as rigid.

In an embodiment a fastener connecting a module to a rail comprises screw threads.

In an embodiment a fastener connecting a module to a rail utilizes snap attachment.

In an embodiment a fastener connecting a module to a rail comprises a plug.

In an embodiment a fastener connecting a module to a rail is electrically conductive.

In an embodiment a fastener is a threaded bolt, and expansion bolt, a metal anchor, a plug, a rivet or U-bolt

In an embodiment a conducting fastener serves to secure a module to a conductive rail and also convey current from said module to the rail.

In an embodiment cells extend over substantially the entire width of a module and the cells are connected in series such that voltage increases progressively in the length dimension of the module while remaining constant over the module width dimension.

In an embodiment a rail is increased in cross section along its length to accommodate increasing current.

In an embodiment a rail serves as a common electrical manifold or buss to convey power from multiple modules.

In an embodiment a rail contributes to conveying current in forming a series connection between adjacent modules.

In an embodiment a portion of the mounting structure may be adjusted vertically to alter the tilt of the module relative to horizontal.

In one embodiment power is conveyed from multiple individual modules at a voltage characterized as non-hazardous.

In one embodiment an existing module may be removed simply and readily replaced with a module of improved performance.

### BRIEF DESCRIPTION OF THE DRAWINGS

The various factors and details of the structures and manufacturing methods of the present invention are hereinafter more fully set forth with reference to the accompanying drawings wherein:

FIG. 1 is a top plan view of a portion of an interconnected photovoltaic cell module useful for the instant invention.

FIG. 2 is a sectional view taken substantially from the perspective of lines 2-2 of FIG. 1.

FIG. 3 is a simplified overall top plan view of an interconnected photovoltaic cell module useful for the instant invention showing some important features contributing to the invention.

FIG. 4 is a perspective view of the module of FIG. 3.

FIG. 5 is a sectional view of a portion of a photovoltaic module comprising the array or module of FIG. 3 plus additional functional components. In the FIG. 5 sectional lines have been omitted for clarity.

FIG. 5A is a side view of a possible process by which a portion of the FIG. 5 structure may be manufactured.

FIG. 6 is a top plan view of a simplified embodiment of a mounting structure.

FIG. 7 is sectional view taken substantially from the perspective of lines 7-7 of FIG. 6.

FIG. 8 is a perspective view showing the overall arrangement of a simplified embodiment of mounting structure prior to installation of photovoltaic modules.

FIG. 9 is a perspective view showing multiple modules (3) installed on the simplified mounting structure of FIGS. 6 through 8.

FIG. 10 is a perspective view exploding the region within circle “10-10” of FIG. 9 and illustrating the details of one form of electrical and structural joining of a module to the mounting structure.

FIG. 11 is a view partially in section further illustrating the details of the mounting arrangement shown in the perspective view of FIG. 10.

FIG. 12 is a view similar to FIG. 11 showing additional optional components of the mounted module.

FIG. 13 is a view similar to FIG. 11 showing a alternate means to electrically and mechanically attach a module to a mounting structure:

FIG. 14 is a view similar to FIG. 11 showing yet another alternate means to electrically and mechanically attach a module to a mounting structure.

FIG. 15 is a perspective view of a mounting structure showing additional functional components.

FIG. 16 shows the mounting structure of FIG. 15 along with two modules as depicted in FIG. 4.

FIG. 17 is a sectional view depicting an alternate component for a mounting structure.

FIG. 18 is a top plan view showing an alternate form of mounting structure.

FIG. 19 is a side view of the mounting structure of FIG. 18.

FIG. 20 is a side view showing the mounting structure of FIG. 19 having a module such as depicted in FIG. 5 mounted thereon.

FIG. 21 is a top plan view of multiple modules mounted as shown in FIG. 20 with the multiple modules interconnected in parallel.

FIG. 22 is a side view partially in section taken substantially from the perspective of lines 22-22 of FIG. 21.

FIG. 23 is a side elevational view similar to FIG. 20 but showing an alternate form of mounting structure.

FIG. 23A is a side view similar to FIG. 23 showing another embodiment of mounting structure.

FIG. 24 is a top plan of another structural embodiment of the novel installations of the instant invention.

FIG. 25 is a perspective view of a portion of the structure depicted in FIG. 24.

FIG. 26 is a top plan view of the mounting structure of FIGS. 24-25 with photovoltaic modules (3) mounted thereon.

FIG. 27 is a view partially in section taken substantially from the perspective of lines 27-27 of FIG. 26 following the installation of a photovoltaic module and rigid fasteners.

FIG. 28 is a view similar to FIG. 27 of an alternate fastening structure for mounting multiple modules.

FIG. 29 is a view similar to those of FIGS. 27 and 28 showing yet another fastening structure for mounting multiple modules.

FIG. 30 is a top plan view showing a array of modules employing both series and parallel interconnections.

FIG. 31 is a top plan view of another embodiment of the novel supporting structures of the instant invention.

FIG. 32 is a sectional view taken from the perspective of lines 32-32 of FIG. 31.

FIG. 33 is a view similar to FIG. 32 following an additional installation step.

FIG. 34 is a view similar to FIG. 33 following an application of additional optional materials to the FIG. 33 structure.

FIG. 35 is a side view of an arrangement to maximize radiation impingement on an array of modules.

### DESCRIPTION OF PREFERRED EMBODIMENTS

Reference will now be made in detail to the preferred embodiments of the invention, examples of which are illustrated in the accompanying drawings. In the drawings, like reference numerals designate identical, equivalent or corresponding parts throughout several views and an additional letter designation may indicate a particular embodiment.

One application of the modules made practical by the above-referenced Luch teachings is expansive area photovoltaic energy farms or expansive area rooftop applications. In this case the installation of the expansive Luch modules can also be facilitated by the teachings of the instant invention.

The instant invention envisions facile installation of large arrays of modules having area dimensions suitable for covering expansive surface areas. In one embodiment, the teachings of the above-referenced Luch patents are used to produce modules of large dimensions. Practical module widths may be 2 ft., 4 ft., 8 ft etc. Practical module lengths may be 2 ft., 4 ft., 10 ft., 50 ft, 100 ft., 500 ft., etc. The longer lengths can be characterized as “continuous” and be shipped and installed in a roll format. As taught in these Luch patents, such large modules can be produced in a flexible “sheetlike” form. In one embodiment, these sheetlike modules are adhered to a rigid supporting member such as a piece of glass, plywood, polymeric sheet, wire mesh or a honeycomb structure.

The sheetlike modules are produced having terminal bars at opposite terminal ends of the module. As used herein, a terminal bar is a region of conductive surface electrically connected to an electrode of an end cell of the interconnected cells. A terminal bar is positioned adjacent or close to an end cell and typically will not extend more than about 6 inches (i.e. 1 inch, 3 inches, 6 inches) from the end cell. In practice, a terminal bar is normally supported by or rests on a material layer that extends to also support the end cell. Also a terminal bar supplies an accessible conductive surface to contact and enable power to be collected from the module. In this regard, alternate structures producing effectively conductive surface regions may be functionally equivalent to the substantially planar terminal bars embodied in the instant figures. Such equivalents include multiple wires or strips extending from the end cell, conductive meshes, conductive ink patterns and the like. All such equivalents are included by the term “terminal bar” as used herein. As will be seen, incorporation of appropriate terminal bars as an integral part of the module construction allows one to make electrical connections from the terminal bar to exterior conductors without junction boxes or unwieldy flexible metallic wire or ribbon leads emanating from the module.

Returning to the above-referenced Luch patents reveals that terminal bars are easily incorporated into the modules using the same continuous process as is used in assembly of the bulk module It is noted that in his patents and applications, Luch taught that the terminal bars may have oppositely facing conductive surface regions with electrical communication between them. In preferred examples, Luch achieved dual sided electrical communication by chemically or electrochemically plating metal through holes extending through an insulating substrate. This is an advantage for certain embodiments of the instant invention. Another advantage of the embodiments of the above-referenced Luch teachings is that terminal bars and the conductive current collector or electrode structure associated with the end cell can comprise a monolithic component forming portions of both the terminal bar and collector/electrode structure. Here the term “monolithic” or “monolithic structure” is used as is common in industry to describe a structure that is made or formed from a single item or material.

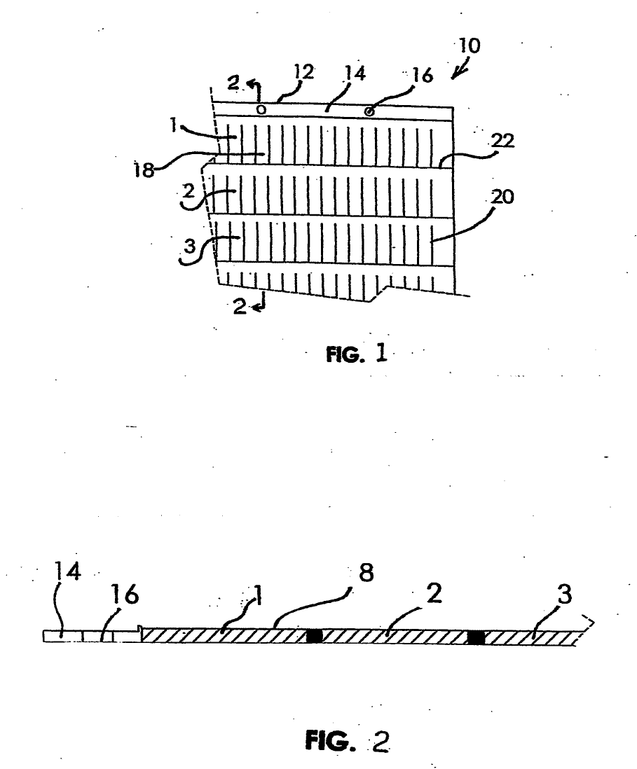

Referring now to FIGS. 1 through 3 of this instant specification, details of a module structure appropriate for the invention are embodied. In FIG. 1, a top plan view of a portion of photovoltaic module 10 is depicted. The FIG. 1 depiction includes one terminal end 12 of the module. Positioned along the edge of the terminal end 12 is electrically conductive terminal bar 14. One understands that a terminal bar of opposite polarity would be positioned at the terminal end opposite terminal end 12 (not shown in FIG. 1). In the embodiment of FIG. 1, through holes 16 have been positioned within the terminal bar 14. As will be shown, through holes 16 may be used to achieve both structural mounting and electrical joining to a mounting structure. In addition, as is clearly taught in the Luch U.S. patent application Ser. Nos. 11/404,168, 11/824,047 and 11/980,010, through holes such as those indicated by 16 may be used to achieve electrical communication between conductive surfaces on opposite sides of an insulating substrate in the terminal bar region. This feature expands installation design choices and may improve overall contact between the terminal bars and conductive attachment hardware.

Continuing reference to FIG. 1 shows photovoltaic cells 1, 2, 3, etc. positioned in a repetitive arrangement. In the embodiment, the individual cells comprise thin film semiconductor material supported by a metal-based foil. This structure is more fully discussed in the above-referenced Luch patents. However, the invention is not limited to such structure. Alternate photovoltaic cell structures known in the art and incorporated into expansive modules would be appropriate for practice of the invention. These alternate structures include thin film cells deposited on polymeric film substrates or superstrates and those interconnected monolithically or by known “shingling” techniques.

On the top (light incident) surface 18 of the cells in the FIG. 1 embodiment, a pattern of fingers 20 and busses 22 function as a current collecting electrode for power transport to an adjacent cell in series arrangement. The grid finger/buss collector is but one of a number of means to accomplish power collection and transport among cells. Methods such as conductive through holes from the top surface to a backside electrode, monolithically integrated structures using polymeric or glass substrates or superstrates, known shingling techniques and “string-and tab” interconnections may also be considered in the practice of aspects of the invention.

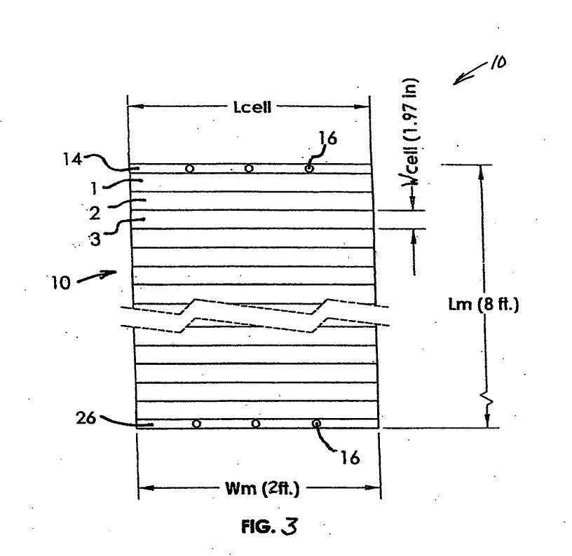

FIG. 2 is a sectional depiction from the perspective of lines 2-2 of FIG. 1. The FIG. 2 embodiment shows a series connected arrangement of multiple photovoltaic cells 1, 2, 3, etc. To promote clarity of presentation, the details of the series connections and cell structure are not shown in FIG. 2. Suitable interconnection structure is taught in the above-referenced Luch applications.

FIG. 3 is a simplified top plan view of a typical module presenting an embodiment of appropriate overall structural features. In the FIG. 3 embodiment, typical overall module surface dimensions are indicated to be 2 ft. width (Wm) by 8 ft. length (Lm). In the following, module dimensions of 2 ft. Wm by 8 ft. Lm will be used to teach and illustrate the various features and aspects of certain embodiments of the invention. However, one will realize that the invention is not limited to these dimensions. Module surface dimensions may be larger or smaller (i.e. 2 ft. by 4 ft., 4 ft. by 16 ft., 8 ft. by 4 ft., 8 ft. by 16 ft., 8 ft. by 100 ft., etc.). There is great latitude in choice of module dimensions or overall form factor, the choice being made to accommodate overall system requirements.

At opposite terminal ends of the module, defined by the module length dimension “Lm”, are terminal bars 14 and 26. Mounting through holes 16 are positioned through the terminal bars 14, 26 as shown in FIG. 2. The module embodied in FIG. 3 has three holes 16 on each of the terminal bars 14 and 16. It will be shown that these holes also contribute to establishing electrical contact to a current carrying bar electrically connecting multiple modules. Thus, the multiple holes contribute to redundancy and security of contact.

In the FIG. 3 embodiment, the module is indicated to have a length (Lm) of 8 ft. However, the module comprises multiple individual cells having surface dimensions of width (W cell) (actually in the defined length direction of the overall module) and length (L cell) as shown. In some embodiments such as that of FIG. 3 the length of the individual cell (L cell) is considerably greater than its width (W cell). Typically cell width (Wcell) may be from 0.2 inch to 12 inch depending on choices among many factors. For purposes of describing embodiments of the invention, a typical cell width (W cell) is suggested as 1.97 inches in FIG. 3 while the cell length (L cell) is suggested to be 2 ft. In the FIG. 3 embodiment, the cell length (L cell) is shown to be substantially equivalent to the module width (Wm). In addition, terminal bars 14, 26 are shown to span substantially the entire length (L cell) of the end cells.

The module 10 of FIG. 3 having an overall length (Lm) of 8 ft. comprises 48 individual cells interconnected in series, with terminal bars 14 and 26 of about 0.7 inch width at each terminal end of the module. Assuming an individual cell open circuit voltage of 0.5 volts (typical for example of a CIGS cell), the open circuit voltage for the module embodied in FIG. 3 would be about 24 volts. This voltage is noteworthy in that it is insufficient to pose a significant electrical shock hazard, and further that the opposite polarity terminals are separated by 8 feet. Should higher voltages be permitted or desired, one very long module or multiple modules connected in series may be considered, employing mounting and connection structures taught herein for the modules. Alternatively, should higher voltage cells be employed (such as multiple junction a-silicon cells which may generate open circuit voltages in excess of 2 volts), the cell width (W cell) may be increased accordingly to maintain a safe overall module voltage. At a ten percent module efficiency, the module of FIG. 3 would generate about 148 Watts.

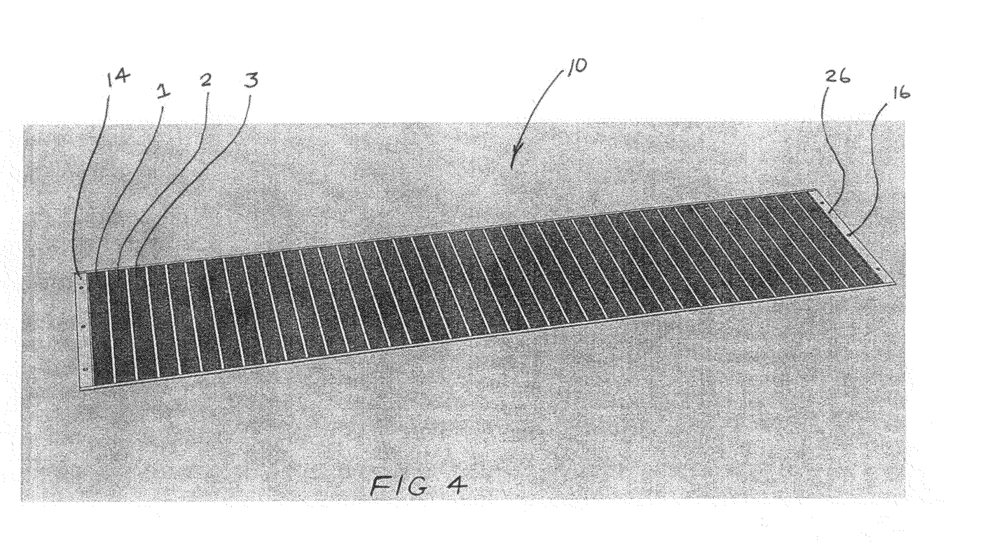

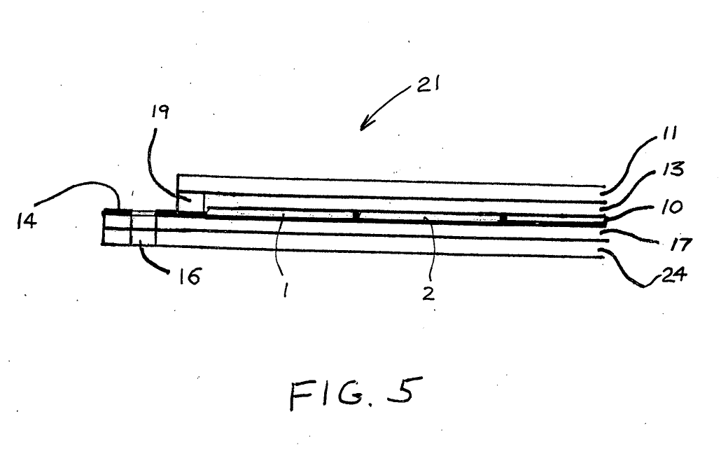

FIG. 4 is an overall perspective view of a module similar to that embodied in FIGS. 1 through 3. At this stage of manufacture, the module embodied will typically be characterized as flexible. A flexible structure will typically deform under small force but return to substantially its original shape upon removal of the force

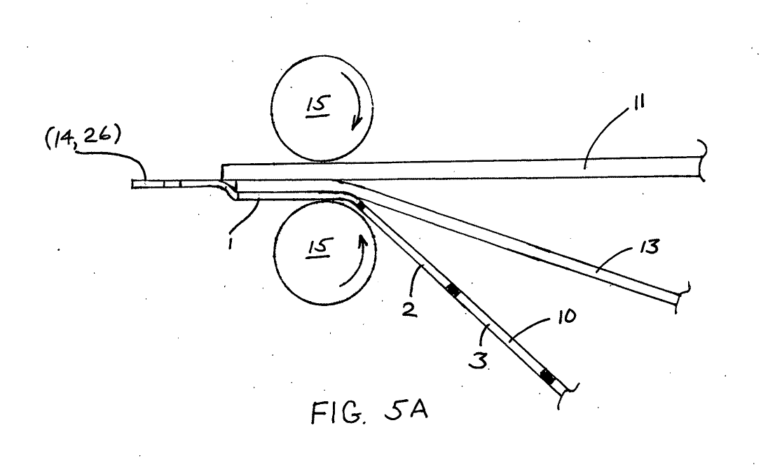

One realizes the module structures depicted in FIG. 1 through 4 may be readily fabricated at a factory and shipped in bulk packaging form to an installation site. Alternatively, additional components may be incorporated at the factory prior to shipment. FIG. 5 embodies such a module structure, generally designated by numeral 21, having additional added components. In FIG. 5, a transparent barrier sheet 11 and optional encapsulant or sealant layer 13 have been applied to the light incident upper surface of module 10. Transparent sheet 11 may comprise glass or a flexible barrier film. Sheet 11 may comprise multiple layers imparting various functional attributes such as environmental barrier protection, adhesive characteristics and UV resistance, abrasion resistance, and cleaning ability

Prior to application of layers 11 and 13, the module 10 is normally flexible: Thus, regardless of whether sheet 11 is flexible or rigid, it may be applied to the module using roll lamination as depicted in FIG. 5A. Glass sheets would normally be considered rigid. Polymer sheets of thickness greater than about 0.025 inch are generally described as rigid. As one understands, the roll lamination depicted in FIG. 5A may have manufacturing benefits compared to other lamination processes such as vacuum lamination. In the roll lamination process of FIG. 5A, the sealant 13 may be heated sufficiently to soften and form a seal between the facing surfaces of the module 10 and sheet 11. Rolls 15 squeeze the warmed composite together to form this surface seal while at the same time expelling a majority of air. In this process the sheets may be preheated prior to entering the rolls or the rolls themselves may be heated to sufficiently soften the sealant layer 13. Alternatively, the sealant 13 may comprise a pressure sensitive adhesive and the process of FIG. 5A may be practiced at room temperature.

Sealant layer 13 may comprise a number of suitable materials, including pressure sensitive adhesive formulations, ionomers, thermoplastic and thermosetting ethylene vinyl acetate (EVA) formulations and the like.

It is understood that once the module is applied to transparent sheet 11, the composite will behave mechanically similar to the transparent sheet. Should sheet 11 be rigid, as is typical for glass or a thick plastic sheet, the composite (module 10/sealant 13/transparent sheet 11) would be characterized as rigid. Should sheet 11 be flexible, as is typical for a thin plastic sheet, the composite will remain flexible.

It is emphasized that the roll lamination process depicted in FIG. 5A is but one form of process capable of creating the (module/sealant/transparent sheet) structure. Other lamination techniques, such as vacuum lamination or simple spreading of sealing material followed by transparent sheet application, may be alternatively employed. In some embodiments, layer 13 may be eliminated and module 10 simply “tacked” to sheet 11.

Returning now to FIG. 5, there is shown additional sheetlike structure beneath the (module/sealant/transparent sheet) composite. In the FIG. 5, numeral 17 points to a “backsheet” structure. Backsheet 17 functions to provide environmental protection and optionally protection against electrical hazard. A number of different backsheet structures exist. For example, backsheet 17 may comprise glass. Alternatively, backsheet 17 may comprise a flouropolymer film or a multilayered structure such as aluminum foil layered onto polyethylene terpthalate (PET). Backsheet 17 may be chosen to be either rigid or flexible. One will understand that backsheet 17 may be applied simultaneously with sheets 11 and 13 during the lamination process depicted in FIG. 5A especially if backsheet 17 is flexible.

Also shown in FIG. 5 is an optional supporting structure 24. Support structure 24 may also supply environmental and electrical protection. The supporting structure 24 may be rigid and may comprise any number of material forms, such as polymeric sheet, a honeycomb structure, expanded mesh, wire mesh or even weatherable plywood. Supporting structure 24 may comprise a composite structure of more than one material. Structure 24 may also incorporate heat conveyance structure to assist in cooling the module. The laminate structure (transparent sheet 11/sealant 13/module 10/backsheet 17) may be attached to the support 24 using standard techniques such as structural adhesives. It is understood that support structure 24 is optional and may possibly be omitted, especially if the module is to be attached to other supporting structure such as a roof or other support structure.

Also shown in FIG. 5 embodiment is sealant strip 19 positioned outside a perimeter defined by the active light absorbing cell surface. In the embodiment, strip 19 is adjacent the periphery of transparent sheet 11. The strip of sealant 19 normally comprises a moisture barrier such as butyl rubber. An additional strip of desiccant material (not shown in FIG. 5) may optionally be placed within the boundary defined by sealant strip 19 in order to absorb any moisture which may migrate through the sealant strip during the life expectancy of the modular construction.

In an embodiment of the invention, a construction similar to that of FIG. 5 is employed but with the elimination of sealant layer 13. This construction leaves a slight air space between the surface of module 10 and sheet 11 but has exhibited excellent performance in accelerated testing when used in conjunction with an internal desiccant as described above.

In FIG. 5, through hole 16 is seen to extend through terminal bar 14, backsheet 17 and supporting structure 24. As will be seen, through holes 16 provide a convenient structure with which to achieve electrical connection and attachment to an eventual mounting structure.

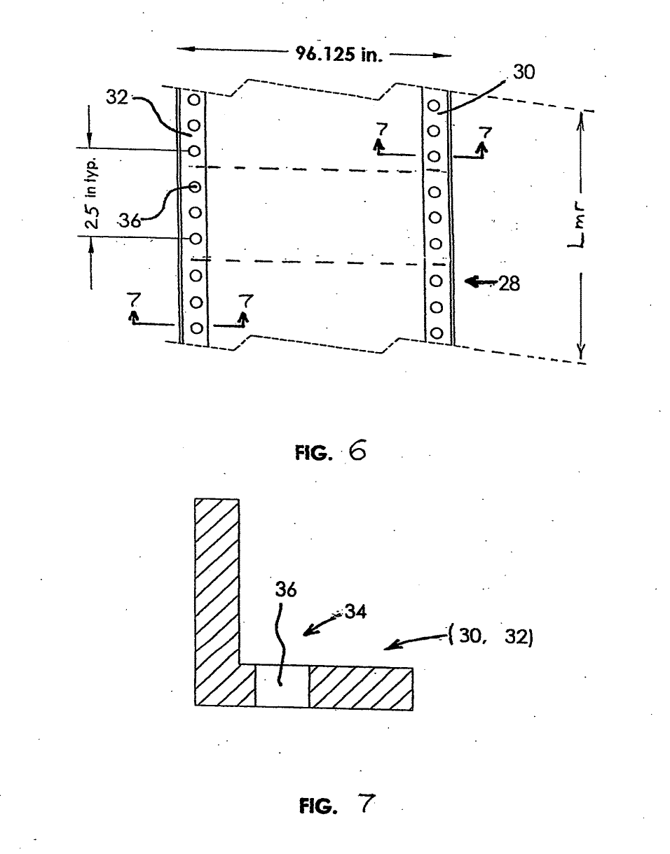

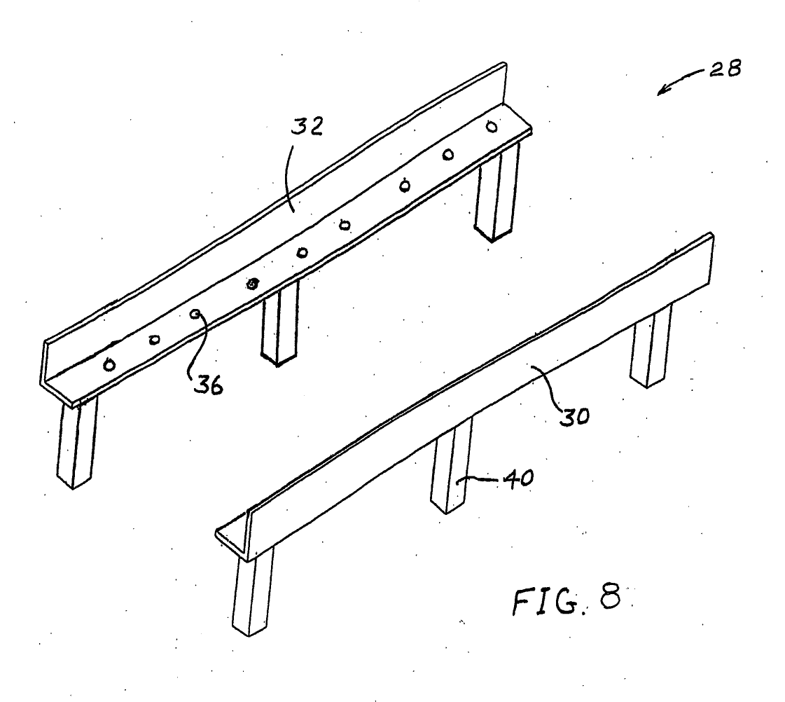

FIG. 6 is a top plan view of a portion of one form of field mounting structure, generally indicated by numeral 28. FIG. 7 is a sectional view taken substantially from the perspective of lines 7-7 of FIG. 6. FIG. 8 is a perspective view of the portion 28. In the structural and process embodiments herein described, mounting structures may be pre-constructed at the site prior to combination with modules 10 such as depicted in FIG. 1 through 4 or module 21 as depicted in FIG. 5. For example, should a terrestrial installation be desired, appropriate land grading and support construction could be completed in advance of the arrival of the modules.

FIGS. 6 and 8 show that the mounting structure 28 comprises 2 parallel elongate rails 30 and 32. In this embodiment, rails 30 and 32 are oriented, spaced and have structure appropriate to readily receive modules. For example, in the embodiment of FIG. 6 the rails have an open or “receiving” dimension (shown as 96.125 inch in the embodiment) slightly larger than a length dimension (Lm) of the FIG. 3 module. The outline of a module such as that of FIG. 3 is depicted in phantom by the dashed lines in FIG. 6. The rails 30, 32 will normally extend a distance (Lmr) greater than the combined aggregate width of a multiple of the expansive surface area photovoltaic modules. A center-to-center distance among modules is suggested as 25 inches in the FIG. 6, indicating about a 1 inch spacing between adjacently place modules.

FIG. 7 is a sectional view taken substantially from the perspective of lines 7-7 of FIG. 6 and shows the details of one form of structure for rails 30, 32. In the FIG. 7 embodiment the rails comprise a 90 degree angle structure of an elongate form of metal such as aluminum. The angle forms a seat 34 to receive the photovoltaic module. Holes 36 through the metal rails are sized and spaced to mate with the holes 16 in modules 10 or 21. Holes 36 may have a smooth bore or be structured such as with a thread pattern to receive a threaded mounting bolt.

The rails may be supported above a base, roof or ground level by piers or posts 40 emanating from the ground or solid surface such as a roof. This elevation allows air flow beneath the modules to cool the relatively thin sheetlike modules. Further, the rails 30, 32 may be at different elevations so as to tilt the arrays at a given angle according to the latitude of the installation site.

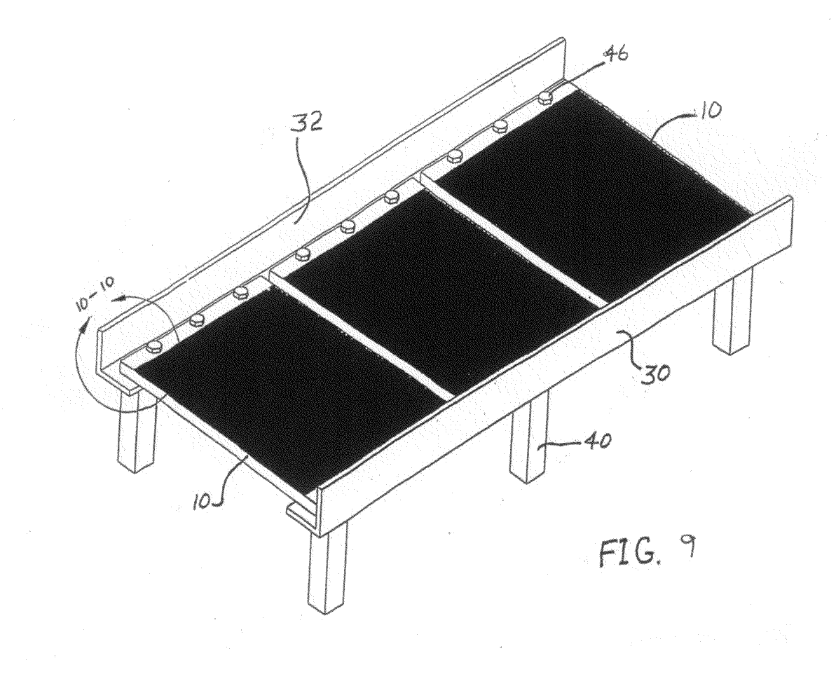

FIG. 9 shows the result of attaching multiple modules (3 in the FIG. 9 embodiment) to the elongate rail structure. The rails have a structure which mates dimensionally with the sheetlike structure of the modules such that the sheetlike modules (10 or 21) are easily positioned appropriately with respect to the rail structure. Electrical connection between the terminal bars 14, 26 disposed at the two opposite ends of the module (10 or 21) and the rails 30, 32 is simultaneously achieved through the mechanical joining of the module to the rails. The terminal bars of a first polarity end of the multiple modules are attached to a first rail and the terminal bars of the opposite polarity are attached to the second opposing rail. It is noted that in this embodiment the multiple modules are connected to rails such that each rail serves as a common manifold for conveyance of power associated with multiple modules and there is no need for coupling of components from the adjacent modules. Thus, current accumulates in the rails as they span multiple modules but the voltage is envisioned to remain substantially constant.

In preferred embodiments the rails 30,32 comprise rigid, elongate metal forms. For example, rails 30, 32 may comprise extruded material forms comprising metals such as aluminum, copper or metal alloys which are relatively inexpensive, rigid, strong and have high conductivity. Most forms of these metals, except for small cross sectional wires and thin sheets, may be characterized as rigid. In this specification and claims, the term rigid is intended to mean a form that is firm and stiff. The rails can comprise more than one metal or alloy. Surface coatings or treatments or additional materials known in the art may be employed to prevent environmental corrosion and deterioration of contacts. As will be shown in the embodiments of FIGS. 8 through 10, the mounting rails 30, 32 may function as power conduits or primary busses from a multiple of individual photovoltaic modules. In order to manage resistive heating losses using such parallel connections among modules, a convenient rule of thumb is that the cross sectional area of the rails be greater than about 0.1 square inch (i.e. 0.1 sq. inch, 0.2 sq. inch, 0.5 sq. inch, 1.0 sq. inch) for every 500 amperes of current conveyed. Elongate forms of most metals and alloys, specifically aluminum, copper and steel, having such cross sections would normally be considered rigid.

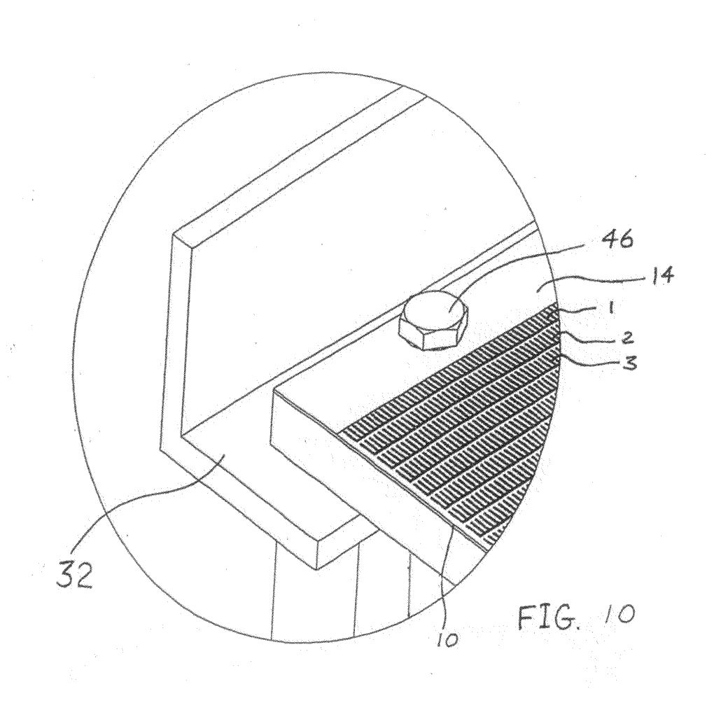

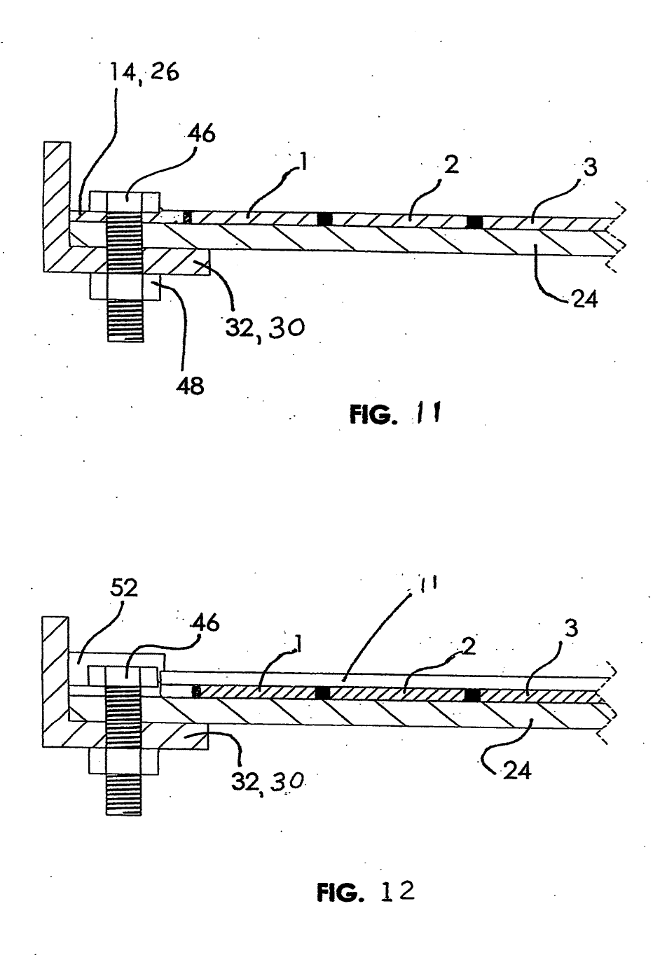

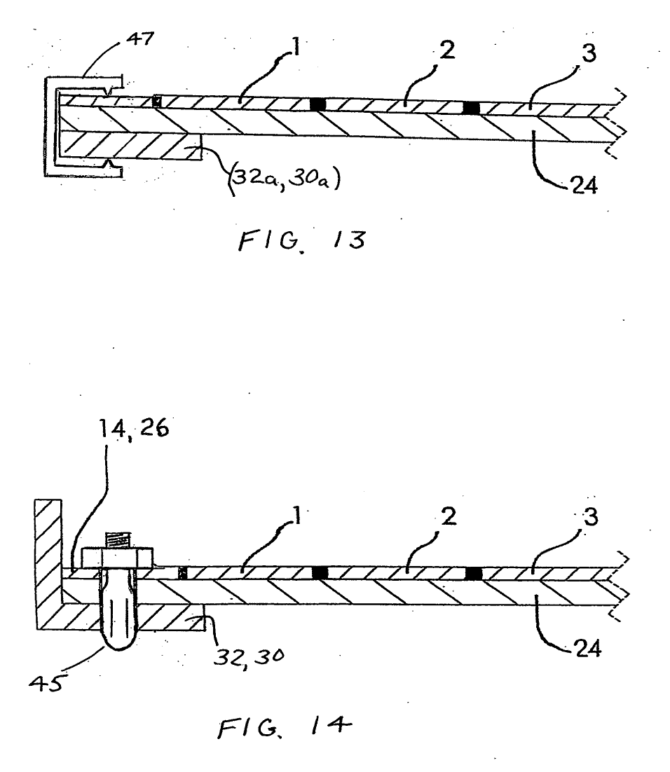

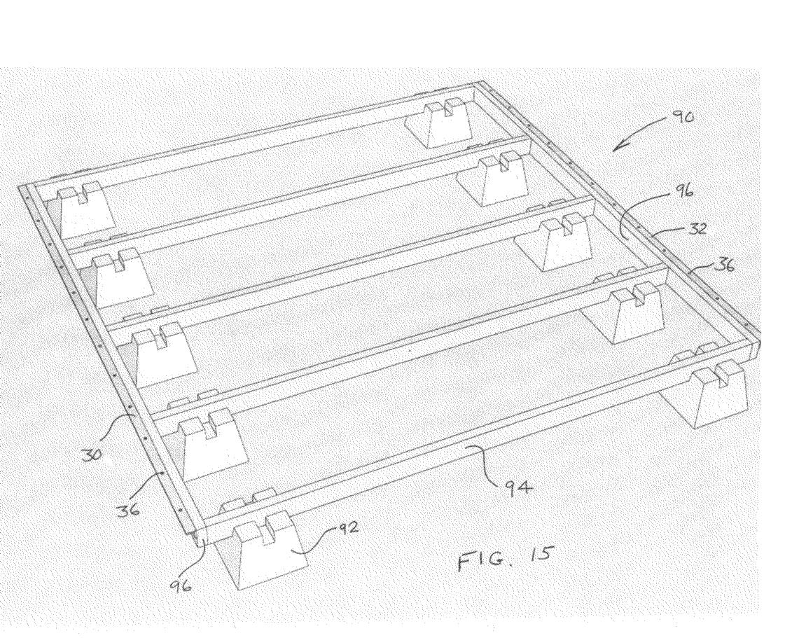

FIGS. 10 through 14 embody details of examples of mechanical joining which simultaneously accomplishes electrical communication between terminal bars 14, 26 and rails 32, 30. The FIGS. 10 and 11 show that the modules are quickly and easily secured to the angled rails using mechanical fasteners such as the metal bolts 46 shown extending through the oppositely disposed module terminal bars, the module support and the metal angle rails. Other conductive mechanical fasteners may be employed such as rivets, clips, banana plugs, expansion bolts (toggle bolts for example) and metal anchors. For example, a spring clip 47 achieves electrical and mechanical connection to flat rails (32a, 30a) in the FIG. 13 embodiment. Banana plug 45 achieves electrical and mechanical connection to the rails (30,32) in the FIG. 14 embodiment. It is noted that the modules depicted in the FIGS. 10, 11, 13 and 14 are shown with supporting structure 24 but are absent components 11 (transparent sheet), 13 (sealant) and 17 (backsheet). The omission of components 11, 13, and 17 is done here for clarity of presentation. One understands that components 11, 13 and 17 may be included without affecting the basic mounting concepts presented in FIGS. 10, 11, 13 and 14.

Other hardware and materials (not shown in the Figures) such as washers and conductive compounds known in the art may be considered to improve surface contact between the conductive mechanical fasteners, terminal bars 14, 26 and rails 32,30 One appreciates that the fasteners should comprises non-corrosive materials such as stainless steel or titanium or employ surfaces and materials assuring longevity of contact. It is noteworthy that no wires or metal ribbons are required to achieve this simultaneous mechanical and electrical joining. Thus there is no need for electrical leads such as unwieldy wires or ribbons emanating from the module. Further there is no need for processes such as soldering to achieve the mechanical and electrical mounting, although such techniques are clearly optional. The mechanical fasteners shown in the FIGS. 10, 11, 13, and 14 embodiments are very robust, quick and simple to install and provide a low resistance connection resistant to breakage and environmental deterioration. In FIG. 9, multiple bolts 46 at each module end (3 shown) minimize contact resistance between the module terminal bars 14, 26 and the angle material and provide redundancy of contact. In this way the power generated in the expansive module is transferred to the supporting rails 32, 30. Thus module mounting and electrical connection to the rail “power conduit” is achieved easily and quickly without any separate wiring requirement. In addition, the mechanical mounting and electrical connection envisioned allows facile removal and replacement of a module should it become defective or future technology produces largely improved performance justifying such replacement.

FIG. 12 embodies a structure similar to FIG. 11 but including an additional rigid or flexible, sheetlike transparent cover 11 for the module which may comprise glass or a transparent polymer sheet such as polycarbonate, acrylic, or PET. As stated above, the purpose on the transparent sheet is to afford additional functional attributes to the module such as environmental protection, abrasion resistance, and cleaning ability. Certain thin film semiconductors such as CIGS are susceptible to environmental deterioration and can be protected by such a transparent environmental cover. It is envisioned that protective cover sheet 11 may be installed after installation of the photovoltaic module to a mounting structure. Alternatively, the cover 11 may be applied at the factory prior to shipment and site installation. It is further envisioned that a sealing member, such as depicted by numeral 52 in FIG. 12, may be employed to fix the transparent sheet in position, provide edge sealing, and further protect the terminal bars and fastening hardware. It maybe advantageous for such a sealing member 52 to be semi-permanent, such as would be the case for a conformable weather stripping material. In this way the module may be easily removed and repaired or replaced as necessary.

As shown in FIG. 9, multiple sheetlike modules (10 or 21) are attached to the rails repetitively in a linear direction along the rails. Each of the modules produces substantially the same voltage, but the current increases each time the rails span an additional module. In this way the installation is a simple placement of the expansive surface modules relative the supporting rails and the mechanical fastening of the modules to the rails (using conductive, mechanical joining means such as nuts and bolts) allows current to flow from the individual module to the rails, with the rails also serving as a conductive buss or power conduit of high current carrying capacity. The elongate rails lead to a collection point where the accumulated power is collected and optionally transferred to a larger master buss for additional transport or the power is converted from “high current/low voltage” to “high voltage/low current” power to achieve more efficient transport.

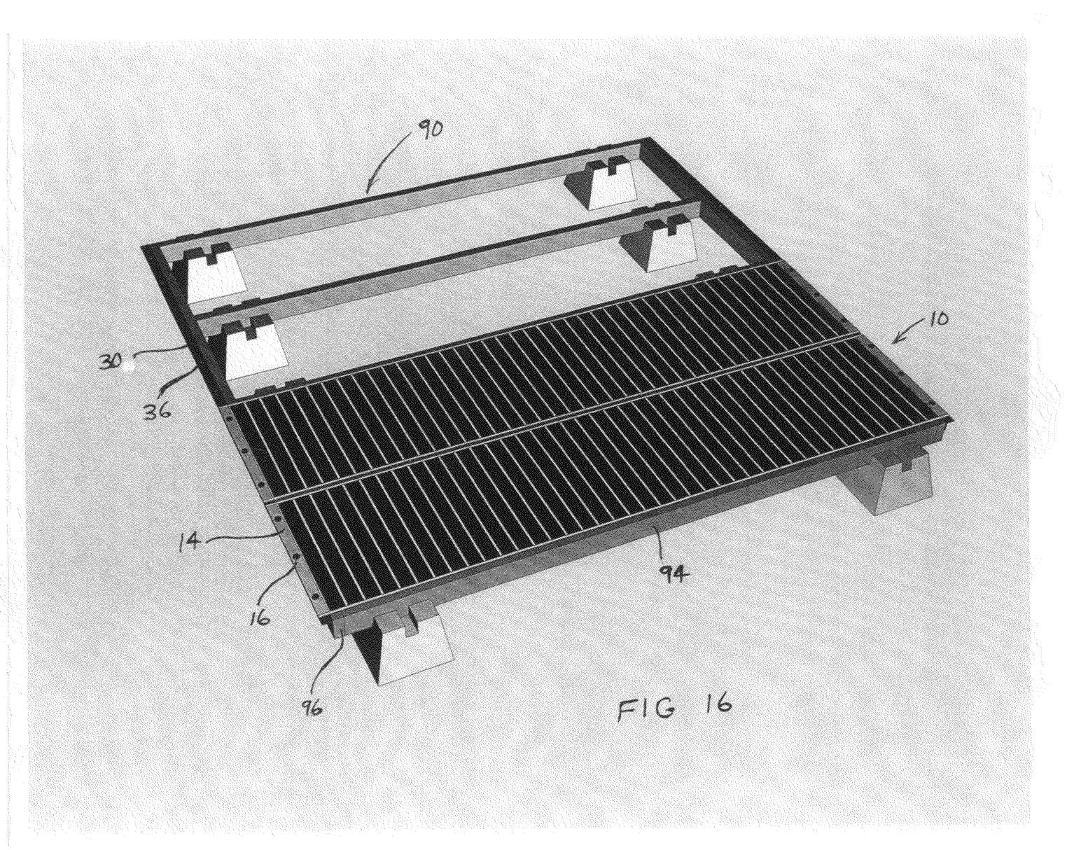

Turning now to FIG. 15, there is shown a perspective view of another embodiment of mounting structure generally indicated by the numeral 90. Mounting structure 90 comprises piers 92 which may comprise the familiar concrete piers used for deck construction. Alternative materials such as recycled polymers may also be employed for construction of such piers. The piers serve not only to support a support lattice above a base surface but may also serve as a weigh ballast to stabilize the structure against environmental conditions. In the embodiment of FIG. 15, the piers are grooved to allow placement of lateral support bars 94. Many choices such as wood, tubular metal or plastics, composites, may be considered for bars 94. Structure 90 also comprises longitudinal support bars 96 extending between multiples of bars 94 as shown. Attached to bars 96 are metal rails (30,32) having mounting holes 36. In this embodiment the rails comprise metal angles mounted to bars 96, oriented to present a flat metallic surface extending outward from the bars 96. In aggregate, structure 90 can be described as a lattice supported and stabilized by piers 92 above a base surface. Additional structure may be included as required to structure 90. For example, additional structural integrity and support may be achieved by additional bars extending between adjacent bars 94 or by attaching a wire mesh screen over the base lattice bars.

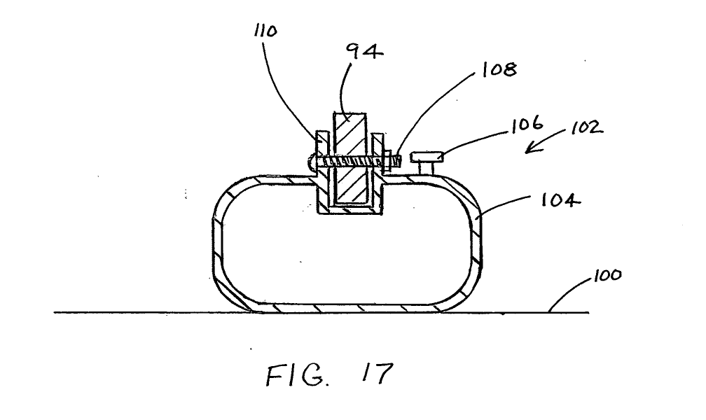

FIG. 16 illustrates the mounting of modules 10 (2 modules shown in FIG. 16) to the mounting structure 90. Holes 16 in the terminal bars of the modules match with holes 36 in the rails (30,32). Conductive mounting hardware (not shown in FIG. 15) electrically and mechanically attach the module to the support structure. Current is conveyed by the rails (30,32) which function as common basses for the assembly of multiple modules.

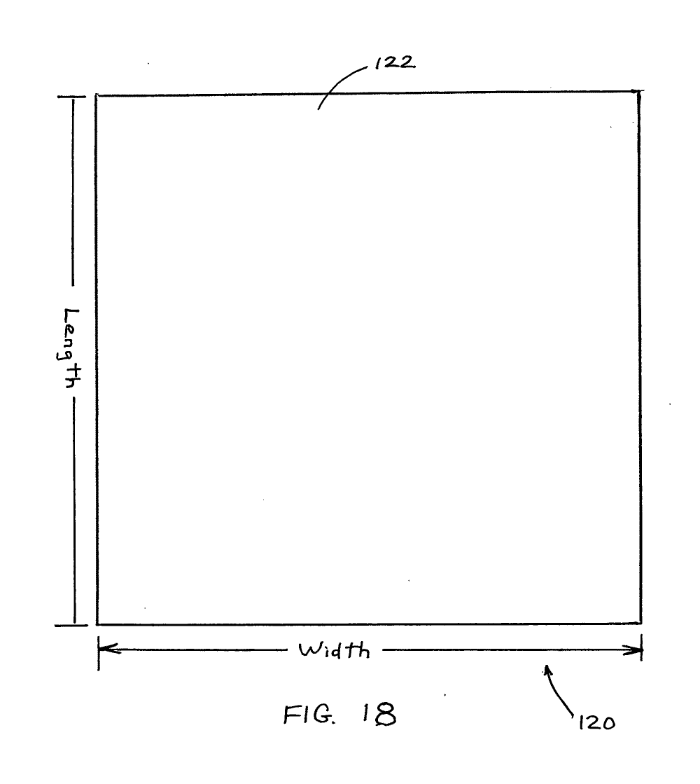

FIG. 17 shows another embodiment of structure 102 to support a lattice-like mounting structure above a base surface 100. Structure 102 comprises a tank 104 having a fill spout and closure 106. Support bars 94 may be attached to tank 104 using standard attachment concepts. In the FIG. 17 embodiment, attachment is achieved using a bolt 108 extending through tank flange 110 and bar 94. Thus, the tanks 104 replace or supplant the posts 40 (FIG. 8) or piers 92 (FIG. 15). In use, tank 104 is filled with liquid such as plain water to supply weight ballast. This arrangement allows shipment and assembly of lightweight components at the installation site and then adding the stabilizing weight to the structure by simply filling the tanks 104 with liquid.

Tank 104 may be constructed from plastic or metal using standard tank manufacturing techniques. Plastic blow molding or injection molding are preferred processes for inexpensive, high volume manufacturing of suitable tanks. Plastic molded tanks are durable and capable of exposure to harsh environments for extended periods.

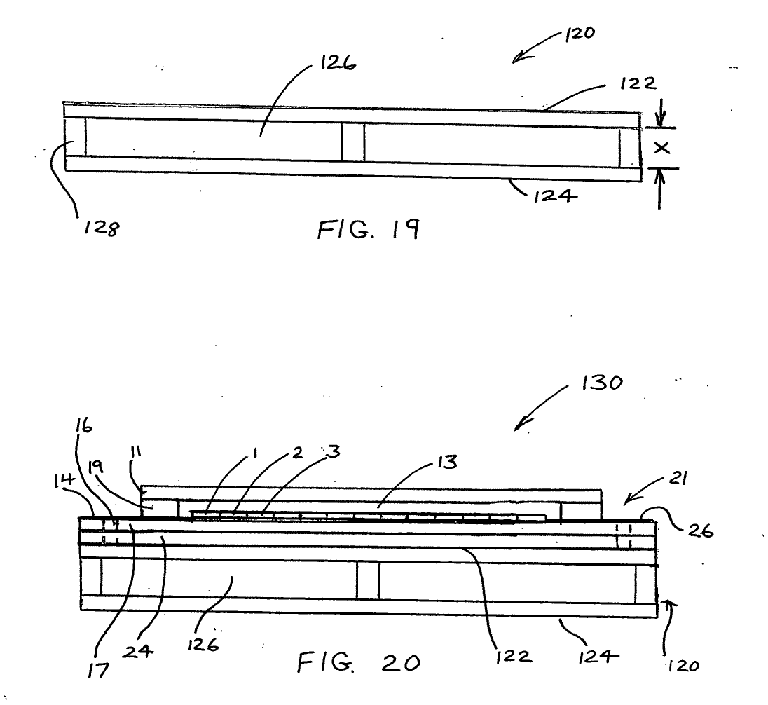

FIG. 18 is a top plan view of another embodiment of a mounting structure identified as 120. FIG. 19 is a side view of mounting structure 120. It is seen that structure 120 comprises a substantially flat top surface 122 and a bottom surface 124. Surfaces 122 and 124 may be solid and formed by continuous sheets of material. Alternatively, surfaces 122 and 124 may be discontinuous and formed by positioned slats, lattice, mesh and the like. Between the materials forming surfaces 122 and 124 is air space 126. The positioning separation between materials forming surfaces 122 and 124 is maintained by positioning spacers or blocks 128.

Referring to FIG. 18, structure 120 has a length and width as indicated. Typical dimensions for both the length and width of structure 120 are 48 inches by 48 inches respectively. Referring to FIG. 19, dimension “X” shown may be typically 4 inches. Given these dimension, one will recognize that structure 120 closely resembles a standard shipping pallet. Such a structure may be easily moved using standard forklift equipment. It also may be easily stacked, transported and distributed. Structure 120 and similar structures will be referred to as “pallets” in the following.

Referring now to FIG. 20, there is shown in side view a combination of the module of FIG. 5 and the “pallet” mounting of FIG. 19. The overall combination is generally indicated by the numeral 130. It can be readily understood that this combination offers the transport and distribution advantages of palletized material along with the positioning, rigidity, and stability of a fixed permanent support structure. In addition, while both support sheet 24 and material forming surface 122 are shown in the FIG. 20, one will recognize that these two components could readily be combined into a single component (i.e. the support sheet 24 could also be the material forming top surface 122 of the “pallet”).

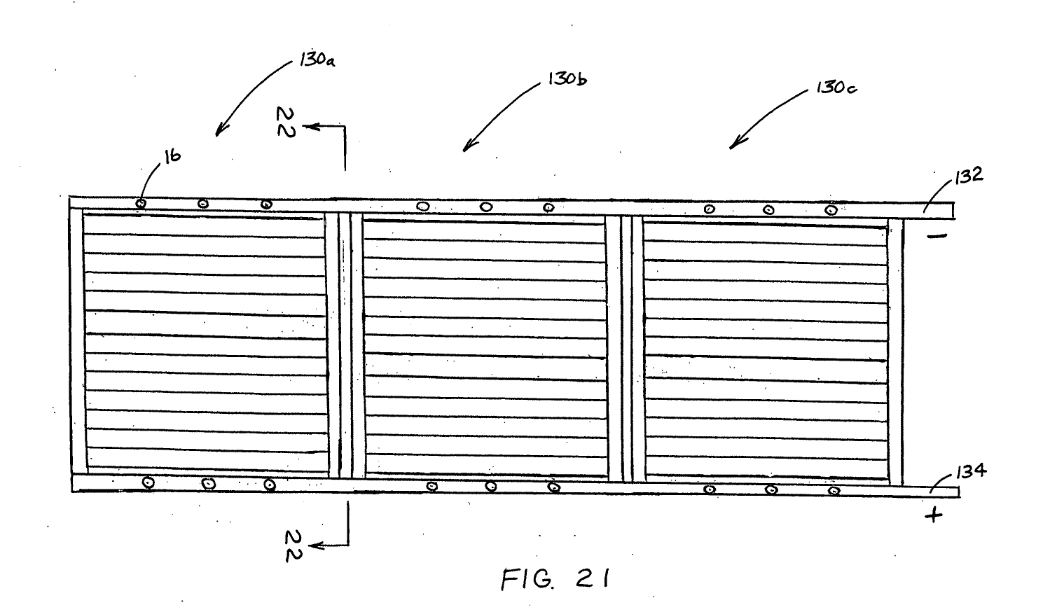

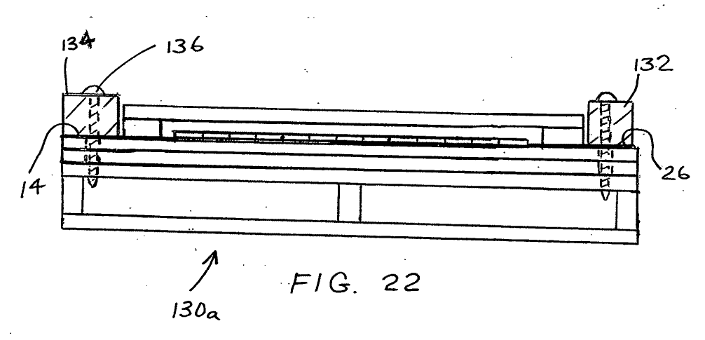

FIG. 21 is a top plan view of an assembled array of 3 of the “palletized” modules (130a, 130b, 130c) of FIG. 20. FIG. 22 is a side view, partially in section, taken from the perspective of lines 22-22 of FIG. 21. Referring to both FIGS. 21 and 22, it is seen that the array of multiple modules is achieved by simply placing the “palletized” modules side by side and then interconnecting them with metallic rails 132 and 134. Each of the rails (132,134) contacts and connects the terminal bars (14,26) from a multiple of adjacently positioned modules 130. The mechanical connection of the terminal rails to the module terminal bars and the underlying “pallet” support is shown to be achieved using simple screws 136. The downward force imparted by the screws also brings the rails (132,134) into electrical contact with the module terminal bars (14,26). Simultaneously, the attachment of the rails to the support “pallets” maintains their adjacent positioning and the long term stability and integrity of the entire assembled array of interconnected modules.

One will realize the structure depicted in FIG. 17 could readily be extended to create a structure of pallet like characteristics. For example, one could simply replace the positioning blocks 128 with small tanks such as embodied in FIG. 17. This would combine the light weight, transportable and modular advantages of the “palletized” module with the convenient weight ballast and stability offered by the liquid filled tanks taught in conjunction with the FIG. 17 embodiment.

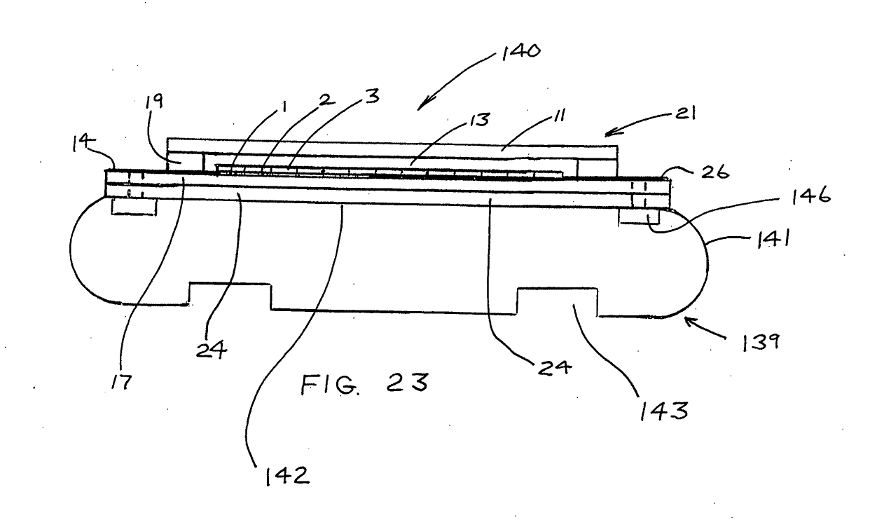

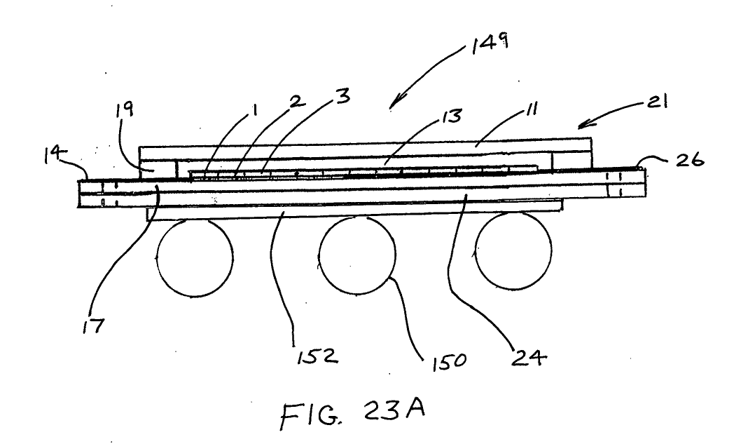

Referring now to FIG. 23, there is embodied yet another form of “palletized” module. The article of FIG. 23, generally designated by the numeral 140, comprises a combination of the module 21 as in FIG. 5 with a large surface area tank, generally indicated by arrow 139. Tank 139 comprises a number of important features. It is, of course, hollow and can contain liquid. Absent liquid, the tank 139 is relatively light weight and therefore the combination article 140 is relatively light weight. However, when the tank is filled with liquid such as water, the combination article 140 significantly increases in weight. Tank 141 has overall dimensions comparable to a conventional pallet, as was the case for the “pallet” of FIGS. 18 and 19. Tank 141 also has depressions or grooves formed in its bottom to accommodate the forks of a forklift. Tank also has formed indentations 146 to accommodate extending hardware (such as a toggle bolt) used to attach a metal rail to the terminal bars (14,26) of module 21. These features can be easily incorporated into plastic tanks produced by conventional blow molding or two part injection molding processing.

To produce the article 140, one simply applies a module such as that of FIG. 5 to the top flat surface of tank 141. Standard structural adhesives may used to adhere the module and tank together. It is noted that because the tank is rigid support sheet 24, while shown in FIG. 23, may possibly be eliminated from this combination. The combination is then transported to the installation site and the modules are arranged adjacent each other. Metal rails, similar to rails 132, 134 of FIG. 22, are then employed to span and interconnect the modules. The interconnection is similar to that shown in FIGS. 21 and 22. However, in the embodiment of FIG. 23, hardware used to electrically and mechanically attach the rails to the terminal bars must not penetrate the tank, so indentations 146 are present to allow extending hardware such as expansion or toggle bolts and rivets. The tanks may then be filled with water to supply ballast and stability to the entire array of interconnected modules.

It has been observed that the water supplying ballast in the modular assembly 140 heats up significantly during the exposure to solar radiation. Thus the arrangement 140 shown in FIG. 23 may also serve as a source of both heated water and electricity. In this regard it is anticipated that tank 141 could be replaced by a grouping of tubes attached to a sheet which itself is attached to module 21. In this case water would be slowly passed through the tubes to generate a continuous stream of hot water during daytime hours and simultaneously cool the modules to give improved electrical performance. An embodiment of such an arrangement, generally identified 149, is illustrated in FIG. 23A. Tubes 150 are secured in geometrical arrangement by sheet 152. Sheet 152 is adhered to the underside of module 21. Water is slowly passed through the tubes at a rate sufficient to heat the water to a desired temperature. Simultaneously, electrical power is collected at terminal bars 14 and 26.

It is noted with reference to FIG. 23A that support sheet 24 shown may be considered for elimination, replaced by sheet 152. It is further noted that proper selection of sheets 11, 17 and 152 would readily permit structure 149 to remain flexible and easily transportable.

Referring now to FIG. 24, another embodiment of an installation structure according the invention is shown in top plan view. This structural embodiment also comprises rails 30a, 32a. In the FIG. 24 embodiment, rails 30a, 32a need not be electrically conductive as will be understood in light of the teachings to follow. Additional cross rails 60 span the separation between rails 30a, 32a. These cross rails 60 have an elongate structure as shown and in an embodiment may be electrically conductive. The repetitive distance between the elongate cross rails is slightly greater than the length (Lm) of a module (for example 96.125 inch for a module of eight foot length). Cross rails 60 also comprise holes 36a which, as will be seen, are positioned to mate with complimentary holes extending through the terminal bars of modules to be eventually positioned on the FIG. 24 structure. Finally, the rails are characterized as having a width dimension (Wm) slightly larger than the width of the eventual module. Thus the rails 30a, 32a, 60 form a convenient receptacle or frame within which a module may eventually be positioned.

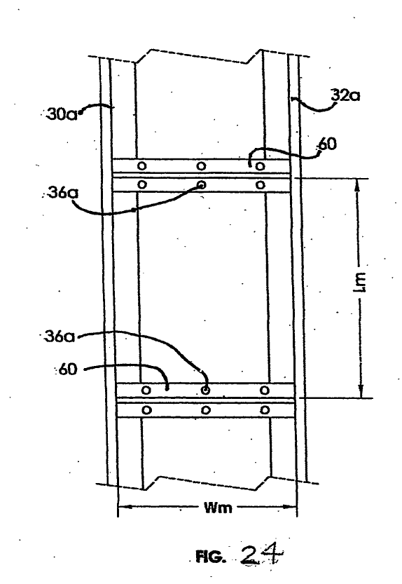

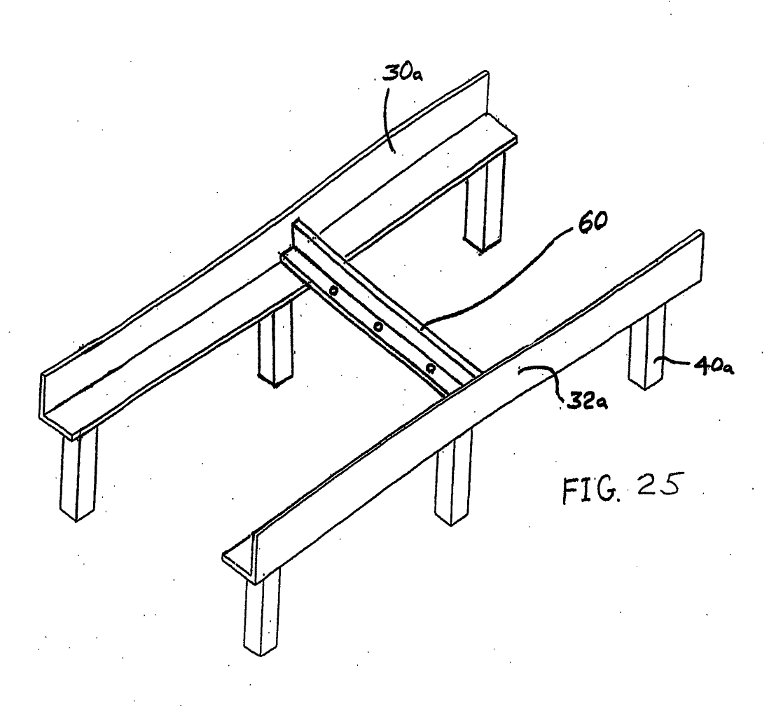

FIG. 25 is a perspective view of a portion of the FIG. 24 structure. In FIG. 25 it is seen that the rail structure 30a, 32a, 60 may be supported on stilts 40a above a base level as previously illustrated for the FIG. 8 embodiment.

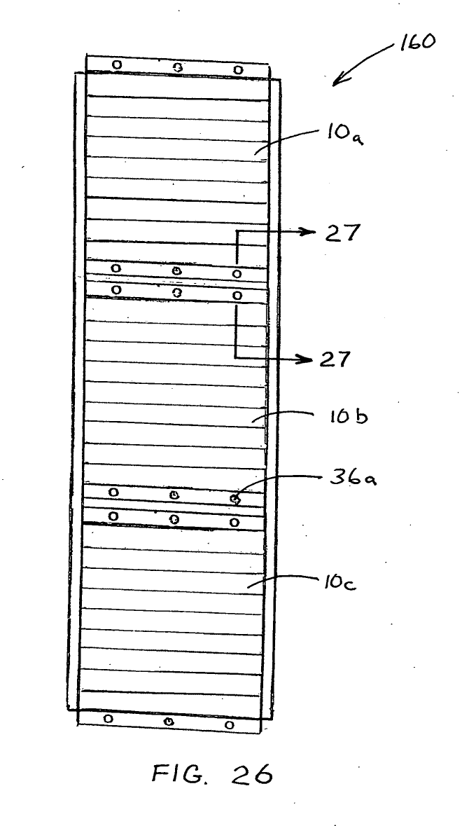

FIG. 26 is a top plan view showing modules 10a, 10b, 10c mounted on the structure of FIGS. 24 and 25. This arrangement is generally indicated by the numeral 160. Holes 36a in the rails 60 align with holes in the module terminal bars. This allow fastening hardware to extend through the holes and accomplish both fastening and electrical communication between the terminal bars of modules and conductive rails.

FIG. 27 is a view in partial section taken substantially from the perspective of lines 27-27 of FIG. 26. In this FIG. 27 embodiment, elongate cross rail 60 comprises electrically conductive material, normally a metal. Two modules are generally indicated in FIG. 27 by the numerals 10a, 10b and the individual series connected cells by the numerals 1a, 1b, etc. FIG. 27 shows that cross rail 60 has the shape of an inverted “tee” having holes 36a on arms 49 and 62 of the “tee”. The terminal bar 14a of module 10b is fastened to a first arm 49 of the “tee” form of cross rail 60 using conducting metal threaded bolts 46a and nuts 48a. The head 47a of bolt 46a contacts a top conductive surface of terminal bar 14a. Additional washers and conductive compounds (not shown) may be used as appropriate to improve surface contact between fastener features and conductive surfaces. Application of the nut 48a securely fastens module 10b to the arm 49 and supplies electrical communication between terminal bar 14a and arm 49. A similar fastening arrangement secures and electrically connects the terminal bar 26a of module 10a to the second arm 62 of cross rail 60. Since in this embodiment the cross rail 60 is conductive, electrical communication is established between terminal bar 14a of module 10b and opposite polarity terminal bar 26a of module 10a. The two modules are thereby simply, inexpensively and robustly connected in series.

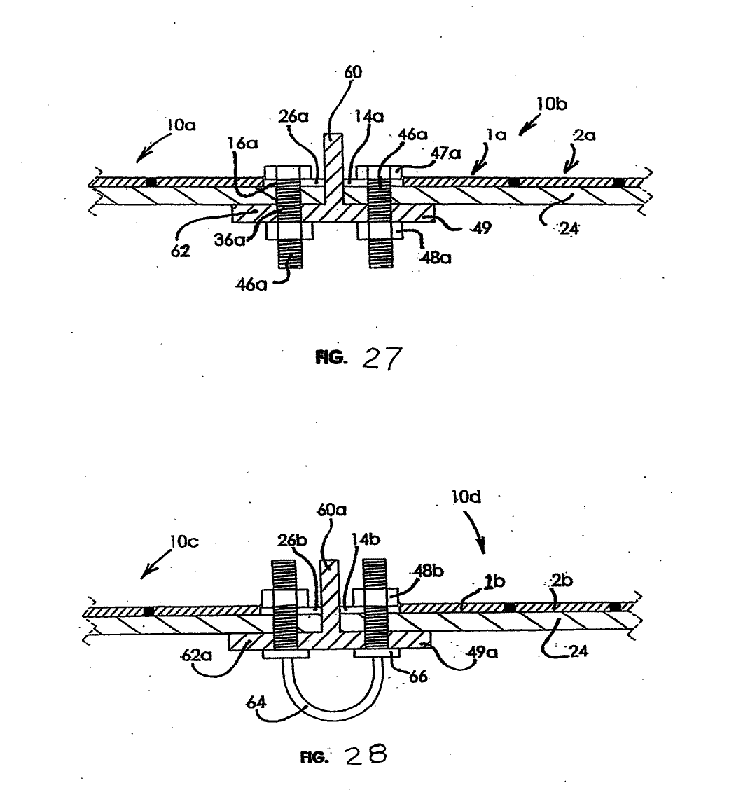

FIG. 28 shows an arrangement partially in section similar to FIG. 27 but illustrating a different form of fastening and connection. In the FIG. 28 embodiment, cross rail 60a is seen to be of cross section similar to that of cross rail 60 in FIG. 13. However, in the FIG. 28 embodiment, elongate cross rail 60a need not necessarily comprise conductive material. In FIG. 28, first terminal bar 14b of module 10d is secured to a first arm 49a of cross rail 60a using one end of a “U-bolt” type connector. In the embodiment, secure attachment of module 10d to rail 60a is achieved by threading of nut 48b such that it pulls flange 66 tightly against the bottom of arm 49a as shown. A similar attachment is made to terminal bar 26b of module 10c. Contact of the respective nuts 48b with the upper conductive surfaces of terminal bars 14b and 26b of modules 10d and 10c respectively connect the two modules in series through the rigid conductive “U-bolt” f fastener. Module mounting is rapid, inexpensive and simple.

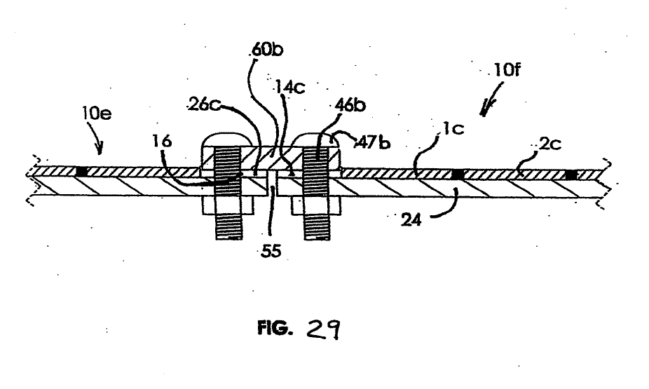

FIG. 29 shows another embodiment of a series connection among adjacent modules. In FIG. 29 the “tee” shaped rails 60 or 60a of FIGS. 27 and 28 respectively are replaced by a simple flat rail in the form of a strap 60b. Modules 10e and 10f may have a slight separation between them as shown at 55 but are in close enough proximity to be described as adjacent. Electrically conductive rail 60b in the form of a conductive metal strap is positioned over the top of terminal bars 14c and 26c on the adjacent modules 10e. Strap 60b has through holes positioned to mate with the through holes on terminal bars 26c and 14c of modules 10e and 10f respectively. Electrically conductive fasteners, in the FIG. 29 embodiment “carriage” type threaded bolts 46b, then secure the strap rail to both terminal bars and thereby a secure and robust electrical connection between terminal bars 26c and 14c is achieved. Simultaneously, the two modules 10e and 10f are affixed in adjacent positioning.

It will be understood that the modules 10 of the embodiments shown in FIGS. 26 through 29 may comprise additional function components such as those presented in the discussion of FIG. 5. These include a transparent cover sheet, sealant layers, backsheets and bottom support layer as previously described in the discussion of the FIG. 5 embodiment.

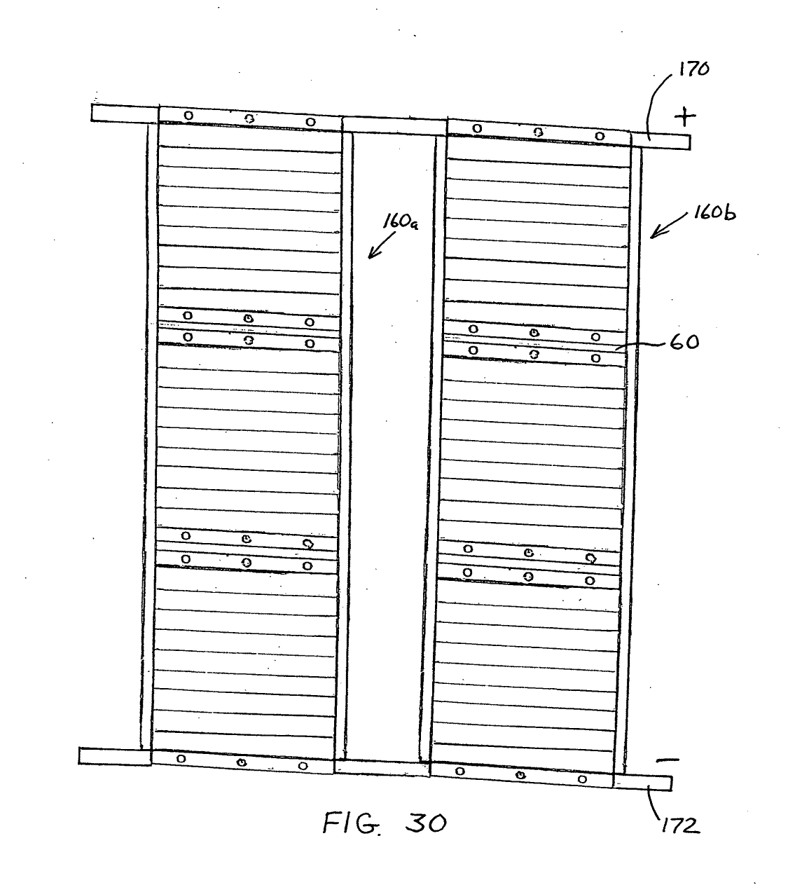

FIG. 30 shows an installation combining the parallel module connections of FIGS. 9, 16, 21 with the series module arrangement illustrated in FIG. 26, In FIG. 30, assemblies of multiple modules connected in series, as depicted in FIG. 26, are indicated by the numerals 160a, 160b. These series connected multi-module assemblies are themselves connected in parallel using conducting busses 170,172 and the techniques taught in regard to FIGS. 8,16 and 21. Conducting busses 170, 172 convey the collected power to a site for central collection or additional processing.

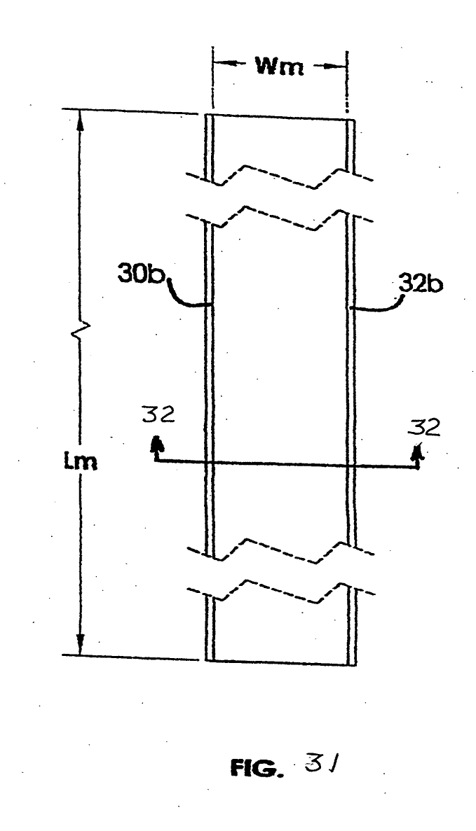

FIG. 31 is a top plan view of another structural embodiment of the inventive installations of the instant invention. FIG. 32 is a sectional view taken substantially from the perspective of lines 32-32 of FIG. 32. Reference to FIGS. 31 and 32 shows a structure comprising a pair of elongated rails 30b and 32b spanned by a rigid supporting sheet 68. Supporting sheet 68 may comprise any number of materials and forms, including honeycomb or expanded mesh forms. Sheet 68 may also be a composite structure of multiple materials and forms, such as backsheet materials and sealants. The combination of rails 30b, 32b, and sheet 68 is seen to form an extended channel, which as will be seen has a width slightly larger than the width of the eventual applied module. One will also understand that this channel may be supported above a ground surface by piers, stilts etc. as previously taugh for prior embodiments.

Continued reference to FIG. 31 suggests that the structure is receptive to a single module having a relatively long length (Lm). Indeed, such a structure is intended to receive and support a module of extended length. While prior art modules have restricted surface dimensions due to fabrication limitations and materials of manufacture, the referenced teachings of the Luch patents and disclosures introduce materials and forms capable of practical production of modules having extended dimensions, particularly in the length direction. Luch teaches technology to produce modules having a length limited only by the ability to properly accumulate them in a roll form. Modules having length in feet of two to three figures (i.e. 10 ft., 50 ft. 100 ft. 1000 ft.) are entirely reasonable using the Luch teachings. Modules having such extended length may be considered “continuous” and transported and installed in roll form. Thus, the dimension (Lm) in FIG. 31 may be considered to be of such extended dimension. Width “Wm” in FIG. 31 may correspond to a module width dimension which may be manageable from a handling and installation standpoint. By way of example, “Wm” may be less than 10 ft. (i.e. 1 ft., 2 ft., 4 ft., 8 ft.) but widths “Wm” greater than 10 ft. are certainly possible.

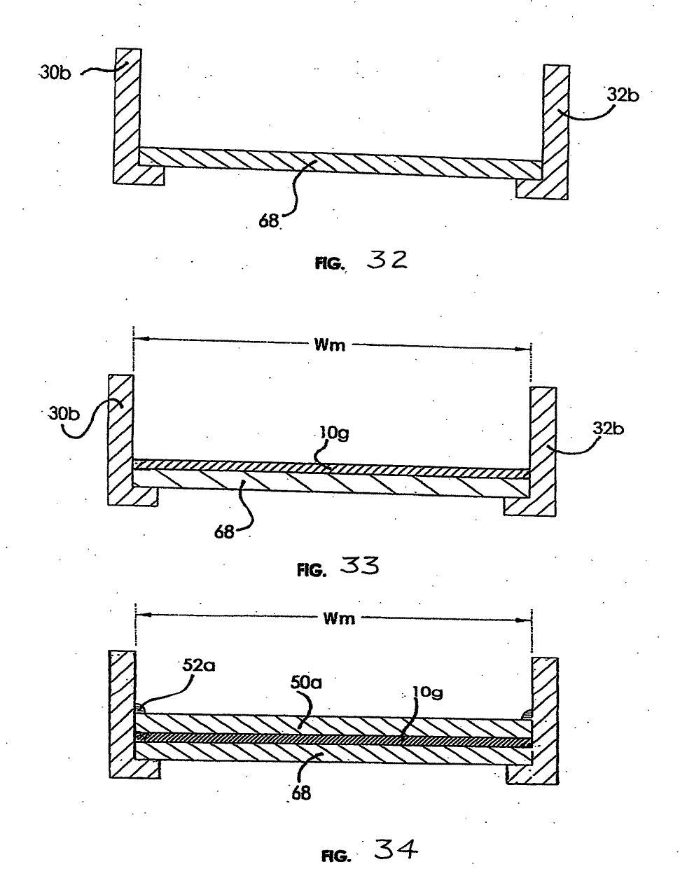

FIG. 33 is a sectional view similar to FIG. 32 following application of a extended length (continuous) form of photovoltaic module 10g. It is envisioned that such a module would be conveyed to the installation site and simply rolled out following the outline of the channel frame formed by rails 30b, 32b and support 68 which is clearly shown in FIG. 32. An appropriate structural adhesive (not shown in FIG. 33) may be used to fix the module 10g securely to sheet 68.

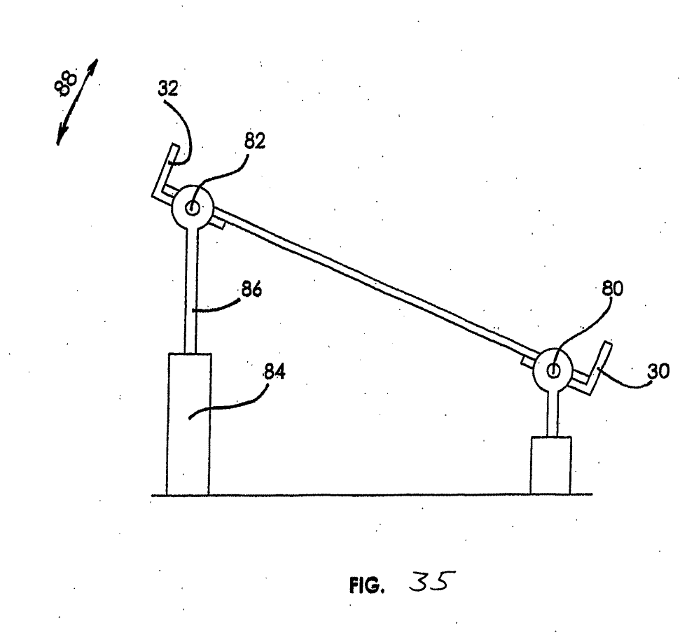

FIG. 34 is a view similar to FIG. 33 but after application of an optional transparent cover sheet 50a and sealing material 52a. As has previously been explained, sheet 50a and sealing material 52a may be useful in extending the life of certain environmentally sensitive photovoltaic materials.

In the supporting structure embodiments shown herein, some embodiments depict “rail” members in the form of material having angled cross sections. While one will realize that such a cross section is not necessary to accomplish the structural and connectivity aspects of the invention, such a geometry forms a convenient recessed pocket or frame to readily receive the sheetlike forms being combined with the structures. In addition, the vertical wall portion of the angled structure offers a containment or attachment structure for appropriate edge protecting sealing materials.

### CONCEPTUAL EXAMPLES

### Example 1

Modules of multiple interconnected cells comprising thin film CIGS supported by a metal foil are produced. Individual multi-cell modules are constructed according to the teachings of the Luch patent application Ser. No. 11/980,010. As noted, other methods of module construction may be chosen. Each individual cell has linear dimension of width 1.97 inches and length 48 inches (4 ft.). 48 of these cells are combined in series extending approximately 94.5 inches in the module length direction perpendicular to the 48 inch length of the cells. Such a modular assembly of cells is expected to produce electrical components of approximately 26 open circuit volts and 18 short circuit amperes. A terminal bar is included to contact the bottom electrode of the cell at one end of the 8 ft. module length. A second terminal bar is included to connect to the top electrode of the cell at the opposite end of the 8 ft. length. The terminal bars are readily included according to the teachings of the referenced Luch patent application Ser. No. 11/980,010. The terminal bars need not be of extraordinary current carrying capacity because their function is only to convey current a relatively short distance and to serve as a convenient structure to interconnect to adjacent mating conductive structure. The individual modules may include appropriate support structure and protective layers as taught above.

In a separate operation, a terrestrial site is selected and prepared. The site may be optionally graded to form a landscape characterized by a combination of repetitive elongate hills adjoining elongate furrows. The linear direction of the elongate hills and furrows and the inclination angle from the base of a furrow to the peak of an adjoining hill is adjusted according to the latitude of the site and possible drainage requirements, as those skillful in the art will appreciate. Mounting piers or stilts are situated to emanate from the ground. (Alternatively, the piers or stilts may be of different heights to accomplish a modular tilt if desired). The mounting piers are positioned repetitively along the length of the hills and furrows. As an example, the piers may be positioned repetitively separated by about 4 to 8 feet, although this separation will be dictated somewhat by the strength of the eventual supporting structure spanning the distance between piers. Finally, a supporting structure, including the elongate rails such as the angled rails as described above, are attached to the piers extending along the length of the hills and furrows. The supporting structure need not be excessively robust, since the modules are relatively light. Should rail strength or current carrying capacity be of concern, other structural forms for the rails, such as box beam structures or increased cross sections, may be employed. Indeed, increased rail cross section may become appropriate as rail length increases.

Installation proceeds by repetitive placement and securing multiple module sheets along the length of the rails. The thin film modules are relatively light weight, even at expansive surface areas. For example, it is estimated that using construction as depicted in FIGS. 5, a 2 ft.×8 ft. module of this example 1 would weigh less than 50 pounds. Thus easy and rapid mounting may be achieved by a 2 man team.

Should the mounting of the modules be in a parallel arrangement such as depicted in FIGS. 9 and 16, the elongate rails are constructed of conductive material such as aluminum or copper. Expected current increases in increments with the placement of each individual module but the expected voltage stays substantially constant along the length of the rails. The expected open circuit voltage from the 2 ft. by 8 ft. conceptual module is a maximum of about 26 volts, not enough to pose an electrical shock hazard. In addition, the oppositely charged rails are separated by 8 ft. Thus the oppositely disposed rails need not be heavily insulated.

A typical length for the rails may be greater than 10 ft. (i.e. 50 ft., 100 ft., 200 ft., 300 ft.) As the expected current increases at greater length, the cross sectional area of the supporting rails may also be increased to accommodate the increasing current without undue resistive power losses. The rails thus serve as the conduit to convey photogenerated power from the multiple modules in parallel connection to a defined location for further treatment.

Should the modules be arranged in series, as depicted in the embodiments of FIGS. 26 through 29, voltage will increase along the length of the mounting structure but the current will remain substantially constant. In the case of the example modules (2 ft.×8 ft. module with cell widths of 1.97 inches and length of 24 inches), the current will remain at about 18 amperes as the power is collected through the multiple modules mounted in series. However, open circuit voltage will increase by about 26 volts as the power traverses each 8 ft. length of module. For a 96 ft. accumulated length of modules, the open circuit voltage will have accumulated to about 312 volts. Thus, in this case precautions must be observed regarding electrical shock danger.

### Example 2

In this example, site preparation is generally similar to that of Example 1 and structures are constructed according to the embodiment of FIG. 31. Modules are manufactured and shipped to the installation site in the form of rolls of extended length. For example, a continuous roll of CIGS cells interconnected in series to form a single module is produced. Individual cells have a width dimension of 1.97 inches and length of 48 inches. The module is 100 ft. in length and has terminal bars at each end of the 100 ft. length. There are 608 series connected cells and the terminal bars are about 1 inch wide and extend across substantially the entire 48 inch width of the module. The modules are accumulated in rolls each of which comprises a 100 ft. module as described.

The rolls are shipped to the installation site. There, workers position one end at the start of an extended channel such as depicted in FIGS. 31 and 32. The module is unrolled using the channel as a guide, optionally using a structural adhesive to fix the module to the supporting structure. A 100 ft. roll of thin film module on a 0.001 inch metal foil substrate is estimated to weigh less than 40 pounds so that the installation could proceed with as little as a two man crew. Electrical connections to a buss bar mounted on the channel's end may be made using the electrically conductive fasteners and techniques such as taught hereinbefore

The extended length module has a total active surface area of 400 square feet. It would be expected to generate approximately 3600 peak watts. Output current would be only about 15 amperes so that conductors need not be overly robust. Closed circuit voltage would be about 310 volts so that safety precautions and security concerns would have to be addressed.

In a comparison of the conceptual examples, the parallel mounting arrangements presented in FIGS. 6, 9, 16, and 21 have the advantage of low shock hazard, easy installation and module replacement. However, this arrangement requires attention to conductor cross sections to minimize resistive losses from high currents. The series arrangement presented in FIG. 26 has the advantage of low currents and therefore low costs of conductors. This arrangement also is characterized by relatively facile installation and replacement. However, this arrangement is characterized by possible high voltage accumulation and requires protection against shock potential. Finally, the extended length module arrangement of FIGS. 31 through 34 may be the simplest installation requiring a minimum of interconnections and facile module shipping and placement. This arrangement produces high voltage buildup and more difficult replacement of defective cells or portions of modules.

Finally it should be clear that while the mounting structures illustrated in the embodiments accomplish supporting modules above a base surface such as the ground or roof, the installation principles taught herein are equally applicable should one use a roof or other surface to support the module.

An additional embodiment of the instant invention is presented in FIG. 35. In the FIG. 35 arrangement one of the mounting rails 30 is mounted on a pivoting support 80. The opposite rail 32 is also mounted to a pivoting support 82. Pivoting support 82 is further mounted to a jacking device 84 as shown. The jacking device 84 may comprise any number of means, such as motorized jack screw or even a hydraulic cylinder. The jacking device 84 provides adjustable extension of arm 86 which accomplishes rotation of the mounted module along an arc generally indicated by double ended arrow 88. Thus, the multiple modules mounted on rails may be conveniently tilted appropriately according to positional latitude or season. Since the modules are relatively large yet lightweight this tilting mechanism may be accomplished with a minimum of complexity.

Although the present invention has been described in conjunction with preferred embodiments, it is to be understood that modifications, alternatives and equivalents may be included without departing from the spirit and scope of the inventions, as those skilled in the art will readily understand. Such modifications, alternatives and equivalents are considered to be within the purview and scope of the invention and appended claims.

What is claimed is:

1. In combination, a photovoltaic module and a conductor,
said photovoltaic module comprising multiple interconnected photovoltaic cells and further comprising a terminal bar,
said conductor comprising a rigid, elongate metallic form positioned exterior said module,
said combination characterized by having said terminal bar electrically connected to said conductor through a mechanical fastener comprising metal.

2. The combination of claim 1 wherein said terminal bar comprises a metallic wire, strip, or mesh.

3. The combination of claim 1 wherein said terminal bar comprises a conductive ink.

4. The combination of claim 1 wherein said terminal bar comprises chemically or electrochemically deposited metal.

5. The combination of claim 1 wherein said module has an end cell and a monolithic material structure forms portions of both said terminal bar and an electrode of said end cell.

6. The combination of claim 1 wherein said conductor comprises aluminum or copper.

7. The combination of claim 1 wherein said fastener comprises stainless steel or titanium.

8. The combination of claim 1 wherein multiple fasteners are used to achieve multiple connections between the terminal bar and the conductor.

9. The combination of claim 1 wherein said electrical connection between said terminal bar and said conductor is achieved absent the use of flexible metallic leads extending to the exterior of said module.

10. The combination of claim 1 wherein said terminal bar has attachment structure intended to mate with complimentary attachment structure present on said conductor.

11. The combination of claim 10 wherein said terminal bar attachment structure comprises through holes.

12. The combination of claim 1 wherein said mechanical fastener is chosen from the group comprising a threaded bolt, an expansion bolt, a metal anchor, a rivet, a U-bolt a spring clip, or a banana plug.

13. The combination of claim 1 further comprising a second of said modules, a terminal bar of the second module electrically connected to said conductor in substantially the same way as said first module.

14. The combination of claim 1 wherein said module has a length and a width, said multiple cells connected in series, said cells having a dimension substantially equal to said module width, said cells arranged such that voltage increases progressively in the direction of said module length while being constant in the direction of said module width.

15. The combination of claim 1 wherein said conductor serves as a buss for conveyance of power produced by a multiple of said modules.

16. The combination of claim 1 elevated above a base plain such that there is an air space between said base plane and said module.

17. The combination of claim 16 wherein said elevation is achieved using a solid pier or liquid filled tank.

18. In combination, a photovoltaic module and a mounting structure,
said photovoltaic module comprising multiple interconnected photovoltaic cells,
said mounting structure comprising a top surface to which said module is attached and further comprising structure allowing the forks of a forklift device to be inserted below said top surface to allow transport of said combination with said device.

19. The combination of claim 18 wherein said mounting structure comprises a pallet.

20. The mounting structure of claim 18 wherein said mounting structure comprises a tank.
